(19) United States
(12) Patent Application Publication
(10) Pub. No.: US 2011/0317116 A1
(43) Pub. Date: Dec. 29, 2011

(54) LIQUID CRYSTAL DISPLAY APPARATUS AND MANUFACTURING METHOD THEREOF

(75) Inventor: Tadashi Kawamura, Osaka (JP)

(73) Assignee: SHARP KABUSHIKI KAISHA, Osaka (JP)

(21) Appl. No.: 13/254,414

(22) PCT Filed: Mar. 3, 2010
(86) PCT No.: PCT/JP2010/001466

§ 371 Date: Sep. 1, 2011

(30) Foreign Application Priority Data
Mar. 4, 2009 (JP) 2009-051321

(51) Int. Cl. G02F 1/1337; G03F 7/20

(52) U.S. Cl. 349/123; 430/319

(57) ABSTRACT

In a liquid crystal display apparatus 100 that includes a pair of substrates and a vertical alignment liquid crystal layer 14, one substrate 1 has a plurality of protrusions 24 substantially in a columnar shape on a surface in contact with the liquid crystal layer 14. The contour of the upper surface of each protrusion 24 on a surface parallel to the substrate 1 includes a linear portion extending in a substabtially straight line along a direction X. The shape of the contour of the upper surface of the protrusion 24 has line symmetry with respect to an axis along a direction Y, does not have line symmetry with respect to an axis along the direction X, and does not have a rotational symmetry axis in the direction normal to the substrate. The ratio W_{Y}/L of the length W_{Y} of the upper surface of each protrusion 24 in the direction Y to the length L of the linear portion is at least 1.6 but no more than 2.5. Viewed from the direction normal to the substrate, the area ratio of the regions where the plurality of protrusions 24 have been formed to the overall surface in contact with the liquid crystal layer 14 is no more than 30%. The liquid crystal molecules located in the middle of the liquid crystal layer 14 in the thickness-wise direction are pretilted towards the direction Y from the direction normal to the substrate when no voltage is applied.

### TECHNICAL FIELD

The present invention relates to a liquid crystal display apparatus and to a manufacturing method thereof.

### BACKGROUND ART

A liquid crystal display apparatus (LCD) is widely used as a display apparatus for computers, televisions, and the like. Until now, horizontal alignment LCDs have been widely used. Horizontal alignment LCDs function in a liquid crystal display mode that uses positive nematic liquid crystal, such as a TN (Twisted Nematic) mode, an STN (Super Twisted Nematic) mode, or the like.

Recently, in order to improve the viewing angle characteristic and display contrast, vertical alignment LCDs using a VAN (Vertically Aligned Nematic) mode are beginning to be put to practical use. A vertical alignment LCD is an LCD in which display is performed in a normally black (NB) mode using a vertical alignment liquid crystal layer disposed between a pair of electrodes.

In order to enhance display contrast in a vertical alignment LCD, orientation in a vertical alignment liquid crystal layer needs to be controlled with increased accuracy and uniformity.

One of the methods for controlling the orientation in a liquid crystal layer is a method in which a pretilt is given in the liquid crystal layer when no voltage is applied (no-voltage state). For example, in a TN liquid crystal display apparatus, which is a horizontal alignment liquid crystal display apparatus, orientation control of liquid crystal has been traditionally performed by controlling a pretilt (pretilt angle, pretilt direction) of liquid crystal molecules using a horizontal alignment film that has undergone a rubbing treatment. Here, the pretilt angle is determined by materials and the like of the liquid crystal layer and of the alignment film, and the pretilt direction is set by the rubbing direction. In such liquid crystal display apparatus, liquid crystal molecules (liquid crystal director) in the liquid crystal layer on a surface of the alignment film are not completely parallel to the substrate when no voltage is applied, and are tilted by approximately 1° to 6° (pretilt angle) in a prescribed direction (pretilt direction). Therefore, when a voltage is applied to the liquid crystal layer (voltage applied state), because liquid crystal molecules try to rise in the pretilt direction, optical response can be changed uniformly and smoothly.

However, in the case of a vertical alignment liquid crystal display apparatus, even when a rubbing treatment is performed to a vertical alignment film that is used for orientation control, the pretilt direction of the liquid crystal layer cannot be controlled stably. Furthermore, because vertical alignment liquid crystal display apparatus has higher contrast than horizontal alignment liquid crystal display apparatus, slight orientation irregularity can be visually observed, and uneven display occurs.

Thus, various methods for controlling the orientation in a vertical alignment liquid crystal display apparatus have been examined. For example, there have been suggested a method in which a protrusion is provided in a pixel (rib method) and a method in which a slit is provided in an electrode (oblique electric field method). According to these methods, liquid crystal orientation can be controlled by a rib structure or by an oblique electric field without performing a rubbing treatment to the alignment film.

In addition to being able to control orientation more stably than the method using the rubbing treatment, using the rib method or the oblique electric field method has another advantage that orientation can be divided relatively easily (MVA mode: Multi Domain Vertical Alignment). In the MVA mode, a plurality of regions (domains) that have mutually different orientation directions (pretilt directions, for example) are provided in a single pixel, and these domains are averaged in size. As a result, the viewing angle characteristic can be significantly improved because an abrupt change of luminance and contrast when a visual angle is changed can be prevented.

As the simplest method for dividing orientation, there has been disclosed a method in which a single pixel is divided into four parts as shown in FIG. 1 (Patent Document 1, for example). Using the method shown in FIG. 1 as an example, orientation division is explained below.

When no voltage is applied, in each quartered region (domain), as shown in FIG. 2(a), liquid crystal molecules 112 (hereinafter referred to as middle liquid crystal molecules) located in the middle of the liquid crystal layer in the thickness-wise direction of each domain are oriented in an approximately perpendicular direction to a surface of a substrate 111 having a vertical alignment film thereon. When a pair of polarizing plates 110 are arranged such that their transmission axes are at right angles to each other through the liquid crystal layer (crossed Nicols state), light is not transmitted through the liquid crystal layer, and display becomes “dark.”

Next, when a voltage is applied to the liquid crystal layer, the middle liquid crystal molecules 112 fall over in a direction set by a rib or an oblique electric field as shown in FIG. 2(b). As a result, light is transmitted by birefringence of the liquid crystal layer. Here, as shown in FIG. 1, if the orientation is divided such that directions (arrows 113) in which the middle liquid crystal molecules 112 fall over are mutually different in these domains, the viewing angle characteristics at each domain are not good, but if four domains are equal in size, an excellent viewing angle characteristics can be obtained.

In order to achieve the aforementioned orientation division without providing a rib or a slit in a pixel, it is necessary to form a vertical alignment film that can have a plurality of domains having mutually different pretilt angles in a single pixel, for example. However, according to the conventional method using the rubbing treatment, the rubbing treatment needs to be performed multiple times (four times, for example) in different directions for the respective regions. Furthermore, there has been a problem of poor division accuracy because this method involves rubbing with a cloth. Thus, it is difficult to put this method to practical use.

However, the rib method and the oblique electric field method have a problem of the reduced aperture ratio and of dark display because a rib and/or a slit is provided in a pixel. Here, the aperture ratio means a ratio of an area that can transmit light in one pixel to the area of the pixel. Furthermore, because of complex structures of substrates and electrodes, these methods have disadvantages such as decreasing productivity and increasing manufacturing cost caused by increased manufacturing processes.

Thus, there has been studied a method in which a vertical alignment film is formed to have a prescribed surface pattern thereon in order to control the pretilt direction of a vertical alignment liquid crystal layer using the surface pattern of the vertical alignment film without using the rubbing treatment. There has been suggested a method in which recessed and projected patterns are periodically arranged and formed at intervals with a fine pitch on a surface of a vertical alignment film, and a method for controlling a surface pattern of a vertical alignment film by providing a vertical alignment film on a base film having a prescribed surface pattern.

For example, there has been suggested a method in which a vertical alignment film is applied on a substrate having a SiO film on its surface by oblique vapor evaporation (Non-Patent Document 1, for example). The SiO film obtained by oblique vapor evaporation has a surface pattern in which fine column shapes (unit structures) have been arranged. According to the method in Non-Patent Document 1, the pretilt direction is controlled by a surface pattern of a SiO film. Furthermore, Non-Patent Document 1 describes that the pretilt angle can be controlled if the surface pattern of the SiO film is adjusted by changing deposition condition.

Patent Document 2 suggests a method in which a surface of a vertical alignment film is embossed using a glass substrate having grooves in a diffractive grating shape, or a substrate having SiO on its surface by oblique vapor evaporation or the like, as a pressing mold.

In both of the methods suggested in Non-Patent Document 1 and Patent Document 2, a structured body, such as a substrate having a prescribed surface pattern, a pressing mold, or the like, is manufactured, and a vertical alignment film having a surface pattern that reflects the surface pattern of such a structured body is formed. However, because these methods use oblique vapor evaporation in order to manufacture such a structured body, they have the following problems.

First, it is difficult to control the surface pattern of the structured body with a high degree of accuracy by oblique vapor evaporation. This problem is especially noticeable when trying to form a unit structure with a fine pitch of less than a few μm, for example, on a surface of a vertical alignment film. Second, the pattern of each unit structure (angle, direction, and the like of a slanted surface of the groove) in the structured body cannot be set flexibly. Because the pattern of the unit structure formed on a surface of a SiO film that has been formed by oblique vapor evaporation depends on deposition conditions, choices of unit structure patterns are limited. As a result, it is difficult to obtain a pretilt having a desired direction or angle, and its use to the display apparatus is limited. Third, if orientation is divided (MVA mode) in order to improve the viewing angle characteristics, it is required to form a vertical alignment film that can have a plurality of regions (domains) having mutually different pretilt directions in a single pixel. When trying to manufacture a structured body in order to form such a vertical alignment film using oblique vapor evaporation, the manufacturing process becomes complex. Furthermore, because the method using oblique vapor evaporation requires at least a certain distance between a vapor evaporation source and a surface of a substrate in order to make the incident angle to the surface of the substrate within a prescribed range, a large apparatus is needed. Thus, this method cannot be applied to manufacturing of a large display device.

Patent Document 3 discloses that an alignment film having a recessed and projected pattern is formed by repeating holographic exposure in different directions multiple times. Even in this forming method, it is difficult to control the recessed and projected pattern with a high degree of accuracy. Furthermore, this manufacturing process is complicated, and is not suitable for mass production.

Non-Patent Document 2 suggests a method in which liquid crystal is vertically oriented by forming recesses and protrusions formed of periodic fine grooves on a surface of a substrate using interference exposure. However, Non-Patent Document 2 does not mention anything regarding providing a pretilt to vertically orient liquid crystal molecules. Furthermore, because the recesses and protrusions explained in Non-Patent Document 2 are obtained by crossing sine wave-shaped interference patterns at a right angle, there is a limit to the choices of shapes and arrangements of the respective fine grooves. In addition, because similar patterns are formed in two directions (direction x, direction y) that are at a right angle to each other, it is difficult to control the patterns in the direction x and in the direction y separately. Therefore, when trying to apply this method to an MVA mode display apparatus, for example, manufacturing process becomes complicated.

Patent Document 4 suggests a method in which columnar protrusions (posts) in a quadrangular column shape, an elliptic column shape, or the like are arranged on a substrate, and the orientation in a liquid crystal layer is controlled using the shape of upper surfaces of the posts. For example, in the case of a quadrangular column, the azimuthal direction of liquid crystal molecules is controlled along one of the two diagonal lines of the quadrilateral on the upper surface. However, even when the azimuthal direction of liquid crystal molecules is controlled, there are two directions in which liquid crystal molecules rise (directions in which liquid crystal molecules fall over) when a voltage is applied because the azimuth 0° and the azimuth 180° are equivalent, and it is difficult to specify one direction.

As described above, there have been suggested methods for forming fine recesses and protrusions on a surface adjacent to a liquid crystal layer in order to control the orientation in a vertical alignment liquid crystal layer. However, it is difficult to appropriately and accurately control the liquid crystal orientation without decreasing the aperture ratio or making the manufacturing process more complicated.

In contrast, in Patent Document 5 by the same applicant as that of the present invention, there has been suggested a method in which using an alignment control structure having a plurality of columnar protrusions arranged therein, orientation control of a vertical alignment liquid crystal layer is performed using a shape of a bottom surface of a recess that is surrounded by the plurality of neighboring protrusions. According to this method, the liquid crystal orientation (pretilt) can be controlled appropriately and accurately. In addition, because the plurality of columnar protrusions are formed, they can be formed in a simpler process, and orientation division can be achieved relatively easily.

### RELATED ART DOCUMENTS

### Patent Documents

Patent Document 1: Japanese Patent Specification No. 2947350
Patent Document 2: Japanese Patent Application Laid-Open Publication No. H3-150530
Patent Document 3: Japanese Patent Application Laid-Open Publication No. H5-188377
Patent Document 4: Japanese Patent Application Laid-Open Publication No. 2001-281660
Patent Document 5: Japanese Patent Application Laid-Open Publication No. 2005-331935

### Non-Patent Documents

Non-Patent Document 1: T. Uchida, M. Ogasawara, M. Wada, Japanese Journal of Applied Physics, Volume 19, 1980, pages 2127-2136.
Non-Patent Document 2: Yoshimitsu Kawai, Isao Irie, Toru Shimamura, Taichi Kagajou, Hiroyuki Okada, Hiroyoshi Onnagawa, “Control of nematic liquid crystal alignment using an ultra-fine periodical structures,” Liquid Crystal Society, 2002, pages 111-112.

### SUMMARY OF THE INVENTION

### Problems to be Solved by the Invention

The alignment control structure disclosed in Patent Document 5 has a surface pattern that is extremely fine. Because of this, it is difficult to manufacture such alignment control structure in a process suitable for mass production. For example, if an exposure apparatus that is highly suitable for mass production (resolution: approximately 0.8 μm, for example) is used, there is a possibility that the alignment control structure is not formed at a sufficient degree of accuracy. As a result, the optimum surface pattern cannot be obtained, and there is a possibility that a desired pretilt is not obtained.

The present invention seeks to address the aforementioned problems, and has a primary object of controlling the liquid crystal orientation at a high degree of accuracy by forming a pretilt in a vertical alignment liquid crystal layer using recesses and protrusions formed on a surface adjacent to a liquid crystal layer. Furthermore, it has an object of forming such recesses and protrusions by a process suitable for mass production.

### Means for Solving the Problems

A liquid crystal display apparatus according to the present invention is a liquid crystal display apparatus provided with a pair of substrates, a vertical alignment liquid crystal layer disposed between the aforementioned pair of substrates, and an electrode that applies a voltage to the aforementioned vertical alignment liquid crystal layer. At least one of the aforementioned pair of substrates has a plurality of protrusions on a surface adjacent to the aforementioned vertical alignment liquid crystal layer, and each protrusion is substantially in a shape of a column. On a surface parallel to the aforementioned one of the substrates, assume that one direction is a direction X and a direction that is orthogonal to the aforementioned direction X is a direction Y. Then, the contour of the upper surface of the aforementioned each protrusion includes a linear portion extending in a substantially straight line along the direction X. The contour shape of the upper surface of the aforementioned each protrusion has line symmetry with respect to an axis along the direction Y; does not have line symmetry with respect to an axis along the direction X; and does not have a rotational symmetry axis in the direction normal to the aforementioned one of the substrates. Assume that the length of the upper surface of the aforementioned each protrusion in the direction Y is W_{Y} and the length of the aforementioned linear portion is L. Then, W_{Y}/L is at least 1.6 but no more than 2.5, and when viewed from the direction normal to the aforementioned one of the substrates, the area ratio of an area where the aforementioned plurality of protrusions have been formed to the overall surface adjacent to the aforementioned vertical alignment liquid crystal layer is no more than 30%. Liquid crystal molecules located in the middle of the aforementioned vertical alignment liquid crystal layer in the thickness-wise direction are pretilted in the direction Y from the direction normal to the aforementioned pair of substrates when no voltage is applied.

In a preferred embodiment, the upper surface of the aforementioned each protrusion has a substantially triangular shape having the aforementioned linear portion as the base.

The aforementioned area ratio preferably is at least 15%. In addition, the aforementioned area ratio preferably is no more than 20%.

The angle between a side of the aforementioned each protrusion and a surface of the aforementioned one of the substrates preferably is at least 70° but no more than 95°.

At least one of arrangement pitches P in the direction X and in the direction Y of the aforementioned plurality of protrusions and a height H of the aforementioned each protrusion preferably satisfy the requirement of 0.15≦H/P≦0.2.

Further, an electrode layer may be provided between the aforementioned one of the substrates and the aforementioned plurality of protrusions, and the aforementioned plurality of protrusions may include a resin layer having columnar structures corresponding to the aforementioned plurality of protrusions, and a vertical alignment film formed on a surface of the aforementioned resin layer. The aforementioned vertical alignment film may be adjacent to the aforementioned vertical alignment liquid crystal layer.

Further, an electrode layer may be provided between the aforementioned one of the substrates and the aforementioned plurality of protrusions, and the aforementioned plurality of protrusions may include a resin layer having columnar structures corresponding to the aforementioned plurality of protrusions, an electrode layer formed on a surface of the aforementioned resin layer, and a vertical alignment film formed on a surface of the aforementioned electrode layer. The aforementioned vertical alignment film may be adjacent to the aforementioned vertical alignment liquid crystal layer.

The aforementioned pair of substrates may include a front substrate disposed on the viewer side of the aforementioned vertical alignment liquid crystal layer and a back substrate that is disposed on the back side of the aforementioned vertical alignment liquid crystal layer and that has a plurality of switching elements. The aforementioned plurality of protrusions may be formed only on the aforementioned front substrate.

The aforementioned pair of substrates may include a front substrate disposed on the viewer side of the aforementioned vertical alignment liquid crystal layer and a back substrate that is disposed on the back side of the aforementioned vertical alignment liquid crystal layer and that has the plurality of switching elements. The aforementioned plurality of protrusions may be formed only on the aforementioned back substrate.

A preferred embodiment has a plurality of pixels arranged in a matrix, and the respective pixels include a first region where the aforementioned direction X is a first direction and a second region where the aforementioned direction X is a second direction that is different from the first direction.

A method for manufacturing a liquid crystal display apparatus according to the present invention includes a step (A) of preparing a substrate having a plurality of protrusions thereon and a step (B) of having the aforementioned substrate and another substrate face each other and of forming a vertical alignment liquid crystal layer between the aforementioned substrate and the aforementioned another substrate.

In a preferred embodiment, the upper surface of the aforementioned each protrusion has a substantially triangular shape, and the aforementioned step (A) has a step (a1) of forming a photoresist layer on the aforementioned substrate and a step (a2) of performing exposure of the aforementioned photoresist layer using a mask having a pattern corresponding to the upper surface of the aforementioned plurality of protrusions. The pattern of the mask includes a unit pattern formed only of a straight line extending in one direction and a straight line extending in another direction that is orthogonal to the aforementioned one direction.

In a preferred embodiment, the aforementioned step (A) includes a step (A1) of preparing a master having a plurality of recesses corresponding to the aforementioned plurality of protrusions thereon and a step (A2) of transferring the surface pattern of the aforementioned master onto a surface of the aforementioned substrate.

In a preferred embodiment, the upper surface of the aforementioned each protrusion has a substantially triangular shape, and the aforementioned step (A1) includes the step (a1) of forming a photoresist layer on a support substrate and the step (a2) of performing exposure of the aforementioned photoresist layer using a mask having a pattern corresponding to the upper surfaces of the aforementioned plurality of recesses. The pattern of the mask includes a unit pattern formed only of a straight line extending in one direction and a straight line extending in another direction that is orthogonal to the aforementioned one direction.

In a preferred embodiment, the aforementioned step (a2) is performed using an exposure apparatus having a resolution of at least 0.5 μm but no more than 1.0 μm, and the aforementioned unit pattern is formed of a combination of a plurality of squares having a length that is equal to the resolution of the aforementioned exposure apparatus as one side, or of a combination of a plurality of larger squares or larger rectangles than these squares.

### Effects of the Invention

According to the present invention, liquid crystal molecules located in the middle of the vertical alignment liquid crystal layer in the thickness-wise direction are given approximately uniform pretilts using a plurality of protrusions arranged on at least one of the substrates on a surface adjacent to a liquid crystal layer. As a result, display having high contrast can be obtained because the liquid crystal orientation can be controlled with a high degree of accuracy. Furthermore, because the orientation of the liquid crystal layer can be controlled in-plane, the response characteristics can be improved. In addition, orientation division can be performed by forming a plurality of regions having protrusions in different directions in a single pixel, and the viewing angle characteristic can be improved.

The aforementioned plurality of protrusions can be formed by a process suitable for mass production. For example, they can be formed using an exposure apparatus (resolution: approximately 0.8 μm) that is generally used in manufacturing a liquid crystal display apparatus. Therefore, according to the present invention, a liquid crystal display apparatus having excellent display contrast can be manufactured in a simple process that is suitable for mass production without increasing the number of manufacturing steps or manufacturing costs.

### BRIEF DESCRIPTION OF THE DRAWINGS

FIG. 1 is a drawing to explain orientation division.

FIG. 2(a) and FIG. 2(b) are drawings to explain the VAN mode.

FIG. 3(a) and FIG. 3(b) are an oblique perspective view and a plan view of an alignment control structure disclosed in Patent Document 5, and FIG. 3(c) and FIG. 3(d) are drawings to explain the concept of orientation control according to the structure shown in FIG. 3(a) and FIG. 3 (b), respectively.

FIG. 4 is a schematic cross-sectional view of a liquid crystal display apparatus of Embodiment 1 according to the present invention.

FIG. 5 is an image showing a columnar structure of a resin layer in Embodiment 1 of the present invention.

FIG. 6(a) to FIG. 6(c) are schematic cross-sectional views of other liquid display apparatuses of Embodiment 1 according to the present invention, respectively.

FIG. 7(a) is a schematic plan view of an alignment control body in Embodiment 1, and FIG. 7(b) and FIG. 7(c) are a plan view and a cross-sectional view, respectively, of a single protrusion in the alignment control body shown in FIG. 7(a).

FIG. 8(a) to FIG. 8(e) are drawings to explain the principle of orientation control in Embodiment 1. FIG. 8(a) is a schematic oblique perspective view of a display apparatus of Embodiment 1. FIG. 8(b) is a schematic oblique perspective view of a single protrusion 24 in Embodiment 1. FIG. 8(c) is a drawing showing the orientation of liquid crystal molecules in a cross-section i that is parallel to substrates 1 and 2 and that includes the upper surface of the protrusion 24 of the substrate 1. FIG. 8(d) is a drawing showing the orientation of liquid crystal molecules in a cross-section ii that is parallel to the substrates 1 and 2 and that is located in the middle of a liquid crystal layer 14 in the thickness-wise direction. FIG. 8(e) is a drawing showing the orientation of liquid crystal molecules in a cross-section iii that is perpendicular to the substrates 1 and 2.

FIG. 9 is a magnified schematic cross-sectional view of a protrusion to explain a tilt angle γ.

FIG. 10(a) and FIG. 10(b) are an image showing a cross-sectional SEM image that shows a portion of a protrusion and an image showing the single protrusion, respectively, when the thickness of the vertical alignment film is 50 nm. FIG. 10(c) is an image showing a cross-sectional SEM image that shows a single protrusion when the thickness of the vertical alignment film is no more than 10 nm. FIG. 10(d) is an image showing a single protrusion (columnar structure of a resin layer) before the vertical alignment film is formed.

FIG. 11(a) to FIG. 11(c) are oblique perspective views illustrating samples of various alignment control bodies (tilt angle γ is below 70°) in this embodiment, respectively.

FIG. 12(a) and FIG. 12(b) are oblique perspective views illustrating samples of various alignment control bodies (tilt angle γ is at least 80° but no more than 90°) in this embodiment, respectively.

FIG. 13 is a graph illustrating a relation between W_{Y}/L (design value) of the upper surface of the protrusion 24 and the tilt angle θ that can be obtained by such protrusion 24.

FIG. 14(a) to FIG. 14(c) are images showing alignment control body samples in which protrusions have been formed. The W_{Y}/L ratios of the protrusions are W_{Y}/L=2.3, W_{Y}/L=3.1, and W_{Y}/L=1.0, respectively. FIG. 14(d) is an image showing an alignment control body sample in which the respective protrusions do not have a linear portion L.

FIG. 15(a) to FIG. 15(d) are two-dimensional simulation results showing changes of the pretilt with various values of W/P, where W/P is a ratio of the width W of a recess (a region where protrusions are not formed) to the arrangement pitch P. FIG. 15(e) is a graph showing a relation between W/P and the tilt angle θ of liquid crystal molecules.

FIG. 16(a) and FIG. 16(b) are plan views illustrating patterns of exposure masks used to manufacture an alignment control body of Embodiment 1, respectively. FIG. 16(c) is a graph showing a relation between the pretilt angle θ and the height of the protrusion obtained by using the masks shown in FIG. 16(a) and FIG. 16(b).

FIG. 17 is a drawing showing a relation between the arrangement pitch of protrusions 24 and the tilt angle θ.

FIG. 18 is a graph illustrating a relation between the height H of the protrusion and transmittance (leaked light).

FIG. 19 is a table showing changes of the pretilt when the ratio W_{Y}/L of the upper surface of the protrusion 24 and the arrangement pitch are changed.

FIG. 20(a) to FIG. 20(d) are cross-sectional views showing process steps to explain a method for forming the alignment control body of Embodiment 1 by photolithography.

FIG. 21(a) to FIG. 21(e) are cross-sectional views showing process steps to explain a method for forming the alignment control body of Embodiment 1 by transferring.

FIG. 22 is a graph showing a relation between transfer pressure and the thickness of a residual film when transfer is performed onto a resin layer.

FIG. 23(a) to FIG. 23(c) are an oblique perspective view, a top view, and a magnified cross-sectional view, respectively, of a transfer resin layer 202.

FIG. 24(a) to FIG. 24(e) are cross-sectional views showing process steps to explain another method for forming the alignment control body of Embodiment 1 by transferring.

FIG. 25(a) to FIG. 25(h) are drawings illustrating unit patterns of the exposure mask, respectively.

FIG. 26 is a plan view showing one example of the exposure mask.

FIG. 27 is a plan view showing another example of the exposure mask.

FIG. 28(a) is a plan view showing a unit pattern of a mask, and FIG. 28(b) is an oblique perspective view showing one example of protrusions obtained by using the mask shown in FIG. 28(a).

FIG. 29(a) is a plan view showing a unit pattern of a mask, and FIG. 29(b) is an oblique perspective view showing one example of a protrusion obtained by using the mask in shown in FIG. 29(a).

FIG. 30 shows simulation results illustrating liquid crystal orientations by protrusions when a conductive film (ITO film) and a vertical alignment film have been formed on a resin layer. FIG. 30(a) shows the orientation of liquid crystal molecules in a cross-section that is parallel to the substrate and that includes the upper surface of the protrusion. FIG. 30(b) shows the orientation of liquid crystal molecules in a cross-section that is parallel to the substrate and that is located in the middle of the liquid crystal layer in the thickness-wise direction. FIG. 30(c) shows the orientation of liquid crystal molecules in a cross-section that is perpendicular to the substrate.

FIG. 31(a) to FIG. 31(c) are simulation results illustrating a relation between the height H of the protrusion and the liquid crystal orientation examined by changing the height H of the protrusion relative to the thickness of the liquid crystal layer, and respectively show the orientation of liquid crystal molecules in a cross-section perpendicular to the substrate.

FIG. 32(a) and FIG. 32(b) are simulation results showing liquid crystal orientations when the shape of protrusions is changed. FIG. 32(a) shows the orientation of liquid crystal molecules in a cross-section that is parallel to the substrate and that includes the upper surface of the protrusion. FIG. 32(b) shows orientations of liquid crystal molecules in a cross-section that is parallel to the substrate and that is located in the middle of the liquid crystal layer in the thickness-wise direction.

FIG. 33(a) and FIG. 33(b) are simulation results illustrating liquid crystal orientations when the shape of the protrusion is changed to a Y-shape. FIG. 33(a) shows the orientation of liquid crystal molecules in a cross-section that is parallel to a substrate and that includes the upper surface of the protrusion. FIG. 33(b) shows orientations of liquid crystal molecules in a cross-section that is parallel to the substrate and that is located in the middle of the liquid crystal layer in the thickness-wise direction.

FIG. 34(a) and FIG. 34(b) are simulation results when orientation control is performed by a recess having a bottom surface in a substantially triangular shape. FIG. 34(a) shows the orientation of liquid crystal molecules in a cross-section that is parallel to a substrate and that includes the upper surface of the protrusion. FIG. 34(b) shows the orientation of liquid crystal molecules in a cross-section that is perpendicular to the substrate.

FIG. 35(a) is a schematic top view showing a single unit region of an alignment control body according to Embodiment 2 of the present invention. FIG. 35(b) and FIG. 35(c) are drawings illustrating other methods for dividing the unit region.

### DETAILED DESCRIPTION OF EMBODIMENTS

In the present invention, liquid crystal molecules (middle liquid crystal molecules) located in the middle of the vertical alignment liquid crystal layer in the thickness-wise direction are pretilted by providing a plurality of protrusions on a surface adjacent to the liquid crystal layer. In this specification, a structure having such a plurality of protrusions may be referred to as an “alignment control structure.” The alignment control structure is provided on at least one of the opposite substrates, such as a TFT substrate, a color filter substrate, and the like of a liquid crystal display apparatus, on a surface adjacent to a liquid crystal layer. In this specification, substrates (including the TFT substrate, the color filter substrate, a glass substrate, and the like) having an alignment control structure thereon are generically referred to as “alignment control body.”

First, a configuration of a conventional alignment control body is explained in detail. As described in Patent Document 5 by the same applicant as that of this application, in order to control the liquid crystal orientation in the thickness-wise direction of a liquid crystal layer, it is effective to deliberately cause a type of an alignment defect near a surface of the vertical alignment film of the liquid crystal layer.

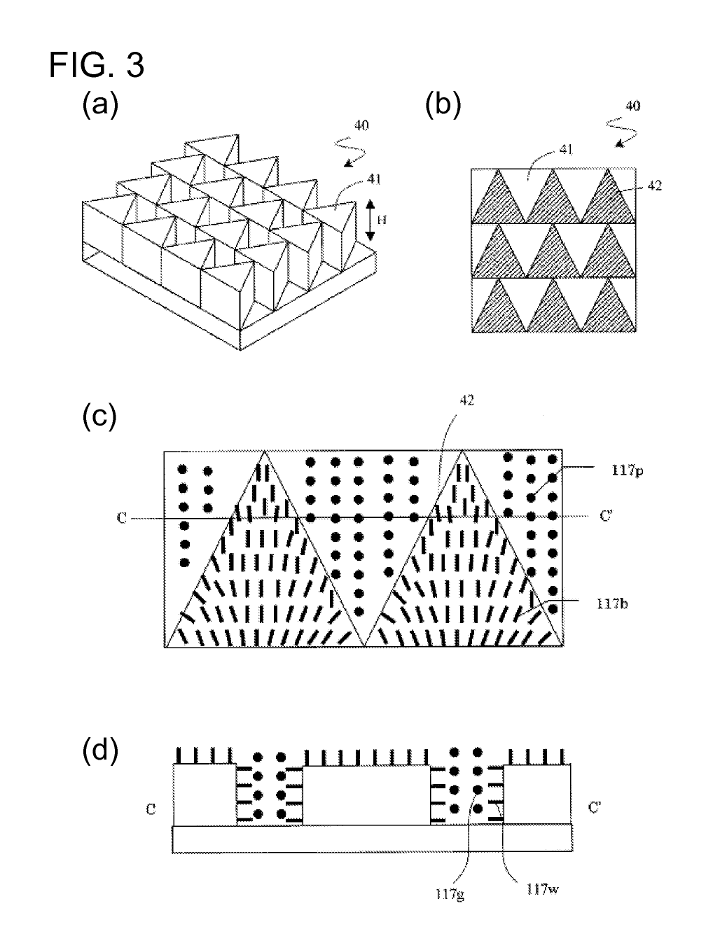

FIG. 3(a) and FIG. 3(b) are an oblique perspective view and a plan view of an alignment control structure disclosed in the aforementioned Patent Document 5, respectively.

An alignment control body 40 has a plurality of unit structures 41 in a triangular column shape. The upper surface of the unit structure 41 is in a shape of an isosceles triangle, for example. As shown in these drawings, a gap (a recess) between neighboring unit structures 41 has a bottom surface 42 in a shape of an isosceles triangle. The liquid crystal orientation can be confined on the bottom surface 42 when liquid crystal is oriented using the alignment control body 40. This principle is explained below with reference to FIG. 3(c) and FIG. 3(d).

FIG. 3(c) and FIG. 3(d) are a plan view and a C-C′ cross-sectional view, respectively, showing orientations of interfacial liquid crystal molecules on an interface between the alignment control body 40 and the liquid crystal layer. As shown in the figure, liquid crystal molecules 117p close to the upper surface of the unit structure 41 are vertically oriented relative to the upper surface of the unit structure 41. On the bottom surface 42 of the gap (recess) between the unit structures 41, liquid crystal molecules 117b are forcedly oriented parallel to the bottom surface 42 and nearly perpendicular to the base of the isosceles triangle of the bottom surface 42. Liquid crystal molecules 117g in the gap between the unit structures 41 are affected by the liquid crystal molecules 117b on the bottom surface 42, and have a roughly same orientation as the liquid crystal molecules 117b. However, liquid crystal molecules 117w located near the respective side walls of the unit structures 41 are oriented perpendicular to the respective side walls of the unit structures 41.

Thus, on the interface between the liquid crystal layer and the alignment control body 40, primarily two types of orientation including the orientation of the liquid crystal molecules 117b on the bottom surface 42 and the orientation of the liquid crystal molecules 117p on the upper surface of the unit structures 41 are obtained. Liquid crystal molecules inside the liquid crystal layer are oriented in a direction obtained by averaging these two orientations, and a vertical orientation tilted in a specific direction is obtained. In other words, orientation control of the inside of the liquid crystal layer can be performed by controlling the aforementioned two orientations given to interfacial liquid crystal molecules.

The unit structures 41 of the alignment control body 40 are arranged with a fine pitch (1 μm, for example). Such fine unit structures 41 are formed by preparing a master (Si mold) using an EB drawing machine (minimum line width: 300 nm), for example, and by transferring the pattern of this master to a UV resin layer. According to this method, unit structures 41 having an upper surface in a shape of an isosceles triangle that is roughly in accordance with the design can be obtained.

However, the aforementioned process using the EB drawing machine is not suitable for mass production. In order to increase mass productivity, it is preferable to use an exposure apparatus such as a stepper or the like that is normally used to manufacture a display apparatus. However, it is difficult to manufacture the alignment control body 40 with a sufficient degree of accuracy using such exposure apparatus. When trying to form the unit structures 41 arranged with a particularly fine pitch (no more than 5 μm, for example), the shape of each unit structure 41 becomes imprecise (shape imprecision) because of the low resolution of the exposure apparatus. As a result, there is a possibility that the optimum alignment control structure cannot be obtained and that an excellent liquid crystal orientation cannot be achieved.

Thus, the inventor of the present invention examined a structure of an alignment control body that can be manufactured using an exposure apparatus normally used to manufacture a display apparatus and by which an excellent liquid crystal orientation can be obtained. As a result, the inventor found an orientation principle that can give a sufficient pretilt to a liquid crystal layer even when a shape imprecision occurs, as well as an alignment control structure based on such an orientation principle. Furthermore, considering the resolution of the exposure apparatus and the shape imprecision, various parameters in the alignment control structure and mask patterns were optimized.

### Embodiment 1

Embodiment 1 of a liquid crystal display apparatus according to the present invention is explained below with reference to figures.

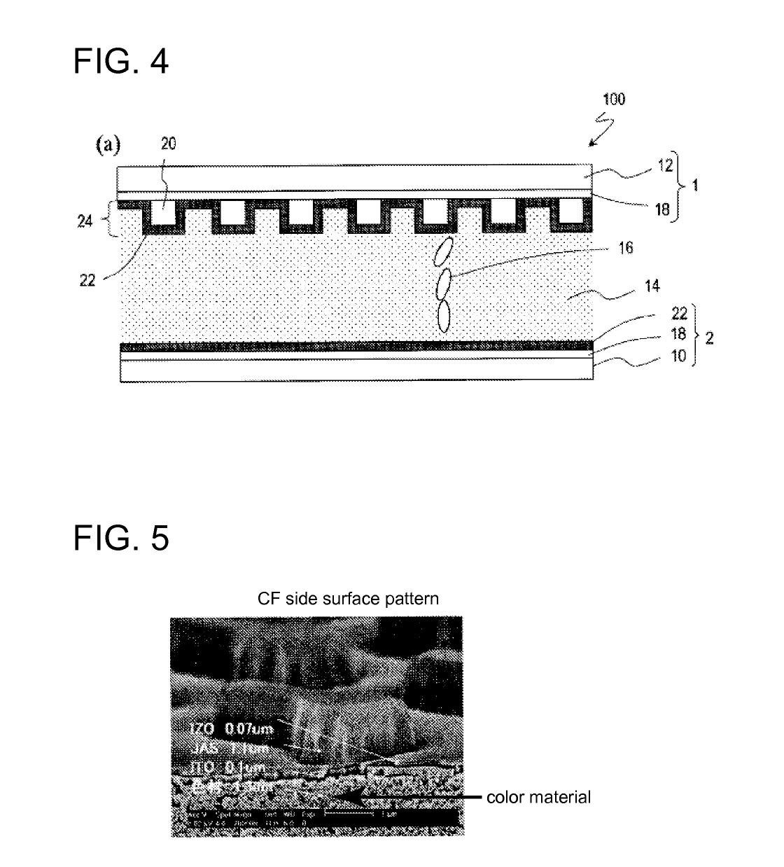

FIG. 4 is a schematic cross-sectional view of the liquid crystal display apparatus of the present invention.

A liquid crystal display apparatus 100 is provided with a back substrate 2, a front substrate 1, and a liquid crystal layer 14 that is disposed between the substrates 1 and 2. The liquid crystal layer 14 is a vertical alignment liquid crystal layer. The back substrate 2 has a TFT substrate 10 that includes a plurality of thin film transistors (TFTs), an electrode layer (here, an ITO layer) 18, and a vertical alignment film 22. The electrode layer 18 and the vertical alignment film 22 are formed on the TFT substrate 10 in this order, and the vertical alignment film 22 is in contact with the liquid crystal layer 14. The front substrate 1 has a CF substrate 12 having a color filter (CF) thereon, the electrode layer (here, an ITO layer) 18, a resin layer 20, and the vertical alignment film 22. The electrode layer 18, the resin layer 20, and the vertical alignment film 22 are formed on a surface of the CF substrate 12 in this order, and the vertical alignment film 22 is in contact with the liquid crystal layer 14. The resin layer 20 includes a plurality of columnar structures. Each columnar structure is nearly in a shape of a triangular column, for example. In order to decrease a voltage drop by the resin layer 20, the resin layer 20 is preferably formed only of a plurality of columnar structures arranged discretely. Alternatively, the resin layer 20 may be a layer having a plurality of columnar structures thereon.

Although not shown in the figure, a polarizing plate is provided on the back side of the back substrate 2 as well as on the viewer side of the front substrate 1. These polarizing plates are arranged such that their transmission axes are at a right angle to each other.

In this example, the front substrate 1 becomes the aforementioned alignment control body. A surface of the front substrate 1 has a plurality of protrusions 24 reflecting a pattern of the resin layer 20. The respective protrusions 24 include columnar structures of the resin layer 20 and the vertical alignment film 22 that coats the surface of the columnar structures. In this specification, column-shaped structured body formed on a surface of the alignment control body in contact with the liquid crystal layer 14 and column-shaped structured body of the resin layer 20 are differentiated by calling the former “protrusion” and the latter “columnar structures.”

FIG. 5 is an image showing the columnar structure of the resin layer 20 in this embodiment. In this example shown, a 0.1 μm-thick ITO layer and a 0.07 μm-thick IZO layer are formed as the electrode layer 18. On the electrode layer 18, a columnar structure (height: 1.1 μm) made of a transparent resin film is formed. The upper surface of the columnar structure is in a shape of an isosceles triangle that is slightly close to a T-shape. In this embodiment, the vertical alignment film (thickness: at least 10 nm but no more than 100 nm, for example) is formed to cover columnar structures such as those shown in the figure and the IZO layer. Therefore, the respective protrusions 24 are in a shape of a triangular column reflecting the shape of the columnar structure. Here, in FIG. 5, an ITO layer and an IZO layer are formed as the electrode layer 18. However, the electrode layer 18 may be constituted of only one layer of the two.

In the liquid crystal display apparatus 100, when a voltage is not applied to the liquid crystal layer 14 (OFF state), liquid crystal molecules 16 included in the liquid crystal layer 14 are affected by protrusions 24 of the front substrate 1, which is the alignment control body, and are tilted from the direction normal to the substrates 1 and 2. When a voltage is applied to the liquid crystal layer 14 by the electrode layers 18 on the substrates 1 and 2, liquid crystal molecules 16 fall over in a direction in which they have been tilted in the OFF state.

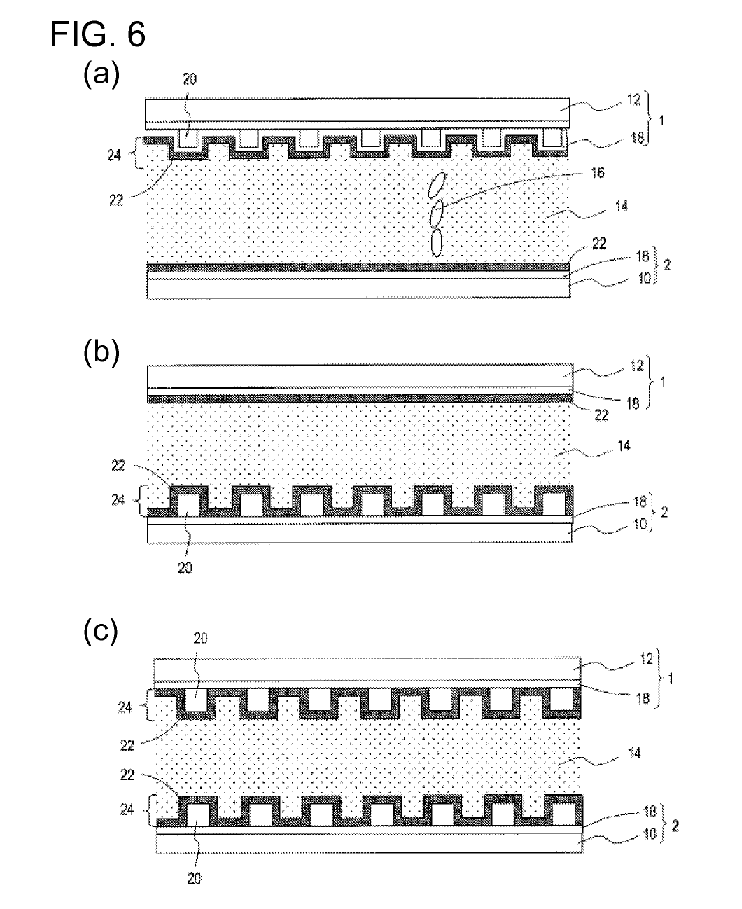

In this embodiment, the electrode layer 18 is formed between the CF substrate 12 and the resin layer 20. However, as shown in FIG. 6(a), the electrode layer 18 may be formed between the resin layer 20 and the vertical alignment film 22. In that case, the protrusions 24 include columnar structures of the resin layer 20, as well as the electrode layer 18 and the vertical alignment film 22 that coat the resin layer 20. Therefore, compared to the shape of the columnar structures, the protrusions 24 have a rounder shape. Therefore, from a perspective of controlling the shape of the protrusions 24 with a higher degree of accuracy, the configuration such that the resin layer 20 is provided on the electrode layer 18 is more preferable.

In this embodiment, a plurality of protrusions 24 are formed on the front substrate 1; however, as shown in FIG. 6(b), a plurality of protrusions 24 may be formed on the back substrate 2 instead. Alternatively, as shown in FIG. 6(c), the plurality of protrusions 24 may be formed on both substrates 1 and 2, thereby forming a configuration such that the liquid crystal layer 14 is disposed between two alignment control bodies. Especially in a display apparatus in a display mode involving a twist, such as an RTN (Reverse Twisted Nematic) mode, it is preferable to provide the plurality of protrusions 24 on both substrates 1 and 2 because orientation directions generated in a liquid crystal layer on the front substrate side and the back substrate side need to be different.

In the case of a display mode that does not involve a twist, the protrusions 24 may be formed only on one of the substrates or on both substrates 1 and 2.

When the protrusions 24 are formed only on one of the substrates, there are following advantages. Manufacturing costs and the number of manufacturing steps can be reduced compared to the case in which the protrusions 24 are formed on both substrates 1 and 2. When the protrusions 24 are formed on both substrates 1 and 2, there is a risk of a moiré occurring because the plurality of protrusions on the substrate 1 and the plurality of protrusions on the substrate 2 interfere with each other. On the other hand, when the protrusions 24 are formed only on one of the substrates, occurrence of a moiré can be prevented, and a more practical display apparatus can be obtained.

On the other hand, when the protrusions 24 are formed on both substrates 1 and 2, the pretilt amount of middle liquid crystal molecules can be doubled compared to the case in which the protrusions 24 are formed only on one of the substrates. As a result, response speed can be increased. Here, even when the protrusions 24 are formed only on one of the substrates, the pretilt of the middle liquid crystal molecules can be doubled by increasing the height H of the protrusions 24. However, when the height H of the protrusions 24 is increased, there is a risk of reduced display contrast. On the other hand, when the protrusions 24 are formed on both the substrates 1 and 2, decrease of display contrast can be prevented by limiting the height H of the protrusions 24, and a pretilt of a prescribed amount can be formed.

The resin layer 20 in this embodiment may include an acrylic resin, such as a photoresist or the like, rubber, an ultraviolet curable resin, a thermosetting resin, an epoxy resin, or the like. Instead of the resin layer 20, a metal layer (Al, Ta, Cu layers, or the like, for example), a semiconductor layer (Si, ITO layers, and the like), or an insulating layer (SiO₂, SiN layers, and the like) may be used. The resin layer 20 made of a material having a property of vertically aligning liquid crystal (a fluororesin or the like) is preferable because the manufacturing process is simplified since there is no need to apply the vertical alignment film 22 on a surface of the resin layer 20.

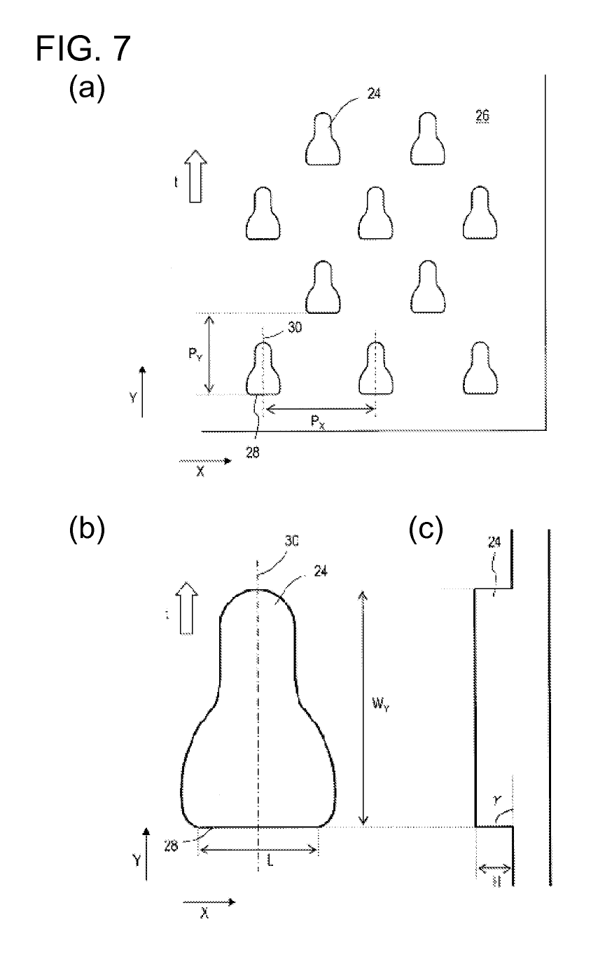

Next, with reference to figures, the structure and the arrangement of the alignment control body in this embodiment are explained. FIG. 7(a) is a schematic plan view of the alignment control body in this embodiment. FIG. 7(b) and FIG. 7(c) are a plan view and a cross-sectional view of the single protrusion in the alignment control body shown in FIG. 7(a) respectively.

The alignment control body of this embodiment has a plurality of protrusions 24 that have a substantially triangular upper surface. On a surface parallel to the substrates 1 and 2, assume that one direction is a direction X and a direction that is orthogonal to the direction X is a direction Y. Then, the contour of the upper surface of each protrusion 24 has a linear portion 28 extending in a substantially straight line along the direction X. Furthermore, the contour shape of the upper surface of each protrusion 24 has line symmetry with respect to an axis 30 along the direction Y, and does not have line symmetry with respect to an axis along the direction X.

Because the alignment control body in this embodiment has the aforementioned plurality of protrusions 24, liquid crystal molecules can be pretilted toward a direction of the arrow t. In this specification, the direction t of the tilt direction of liquid crystal molecules (liquid crystal director) on a surface of the substrates 1 and 2 is a “pretilt direction,” and the tilt angle of liquid crystal molecules from the line normal to the substrate is a “pretilt angle.” When the pretilt angle is 0°, it means that the long axis direction of liquid crystal molecules is perpendicular to the substrates.

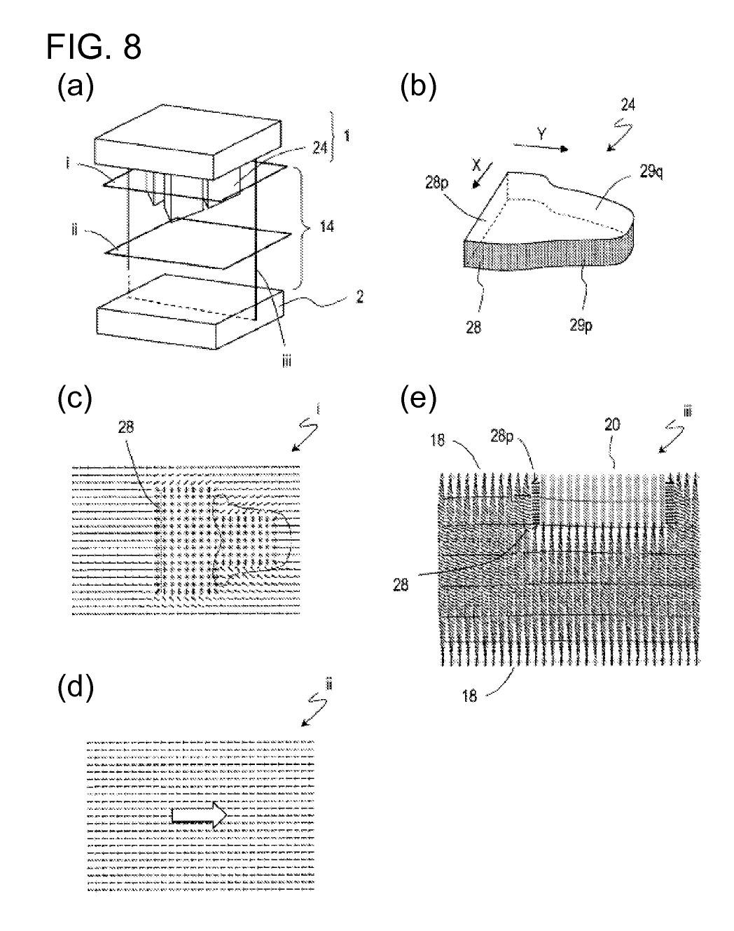

The principle of orientation control according to this embodiment is explained below with reference to FIG. 8.

FIG. 8(a) is a schematic oblique perspective view of the display apparatus of this embodiment, and FIG. 8(b) is a schematic oblique perspective view of the single protrusion 24 in this embodiment. To facilitate explanation, the same reference characters are given to the components that are similar to those in FIG. 4, and explanation thereof is omitted. FIG. 8(c) is a drawing showing the orientation of liquid crystal molecules in a cross-section i that is parallel to the substrates 1 and 2 and that includes the upper surface of the protrusion 24 of the substrate 1. FIG. 8(d) is a drawing showing the orientation of liquid crystal molecules in a cross-section ii that is parallel to the substrates 1 and 2 and that is located in the middle of the liquid crystal layer 14 in the thickness-wise direction. FIG. 8(e) is a drawing showing the orientation of liquid crystal molecules in a cross-section iii that is perpendicular to the substrates 1 and 2. Curved lines shown in FIG. 8(c) and FIG. 8(e) are equipotential lines.

As shown in FIG. 8(c), liquid crystal molecules near the upper surface of the protrusion 24 are vertically oriented relative to the upper surface of the protrusion 24. Liquid crystal molecules located near the respective side walls 28p, 29p, 29q (FIG. 8(b)) of the protrusion 24 are oriented perpendicular to the respective side walls of the protrusion 24. As described, in the cross-section i, there are different liquid crystal orientations. In addition, as shown in FIG. 8(e), liquid crystal molecules on a part of the surface of the substrate 1 where the protrusions 24 have not been formed (referred to as a “recess”) are vertically oriented relative to the substrate 1. As a result, in a region (space) located between the side wall 28p of the protrusion 24 and the surface of the substrate 1, a part where liquid crystal orientation is confined (orientation defect) is formed. Because of this, the liquid crystal orientation by the side wall 28p becomes difficult to be communicated in the thickness-direction of the liquid crystal layer 14. Therefore, the tilt direction of liquid crystal molecules in the middle of the liquid crystal layer 14 in the thickness-direction is primarily controlled by two orientations: the orientation of liquid crystal molecules located near the side walls 29p and 29q and the orientation (vertical orientation relative to the substrate 1) of liquid crystal molecules located on the upper surface of the protrusion and on the recess.

Here, because the contour shape of the upper surface of each protrusion 24 has line symmetry with respect to the axis parallel to the direction Y, components along the direction X in liquid crystal orientations by the side walls 29p and 29q cancel out each other. As a result, liquid crystal molecules inside the liquid crystal layer 14 are oriented in a direction obtained by averaging the components along the direction Y in liquid crystal orientations by the side walls 29p and 29q and the liquid crystal orientation vertical to the substrate 1. Therefore, liquid crystal molecules near the middle of the liquid crystal layer 14 in the thickness-direction (referred to as “middle liquid crystal molecules”) have a director in a direction that is tilted only by a prescribed angle (pretilt angle) toward the direction of the arrow (pretilt direction) from the normal line to the substrate, as shown in FIG. 8(c) and FIG. 8(e). The pretilt direction is a direction from the linear portion 28 that is the base towards the apex in a nearly isosceles triangle of the upper surface of the protrusion 24 (direction Y). In this specification, the “pretilt angle” is an angle formed by the tilt direction of the long axis of liquid crystal molecules relative to a line normal to the substrate.

Here, it is required that the contour shape of the upper surface of the protrusion 24 in this embodiment does not have line symmetry with respect to the axis parallel to the direction X. This is because a pretilt cannot be formed in a specific direction because components along the direction Y in liquid crystal orientations by the side walls 29p and 29q would cancel out each other if there were such line symmetry.

It is required that the contour shape of the upper surface of the protrusion 24 does not have rotational symmetry with respect to the axis along the direction normal to the substrates 1 and 2. This is because liquid crystal molecules cannot be oriented in a desired direction if there is such rotational symmetry. For example, if the upper surface of the protrusion 24 is an equilateral triangle having three rotational symmetry axis in the direction normal to the substrates, liquid crystal molecules try to be oriented along three directions that are perpendicular to the respective sides of the equilateral triangle. As these three liquid crystal orientations are averaged, liquid crystal molecules located in the middle of the liquid crystal layer 14 in the thickness-wise direction cannot be pretilted.

As described above, orientation control in this embodiment is based on a principle that is completely different from the principle disclosed in Patent Document 5 that has been explained with reference to FIG. 3(c) and FIG. 3(d). In Patent Document 5, as described above, the pretilt is controlled by the shape of the bottom surface surrounded by a plurality of neighboring protrusions. Therefore, an interval between neighboring protrusions had to be small and the shape of the bottom surface had to be controlled with an extremely high degree of accuracy. Accordingly, manufacturing using an exposure apparatus normally used in a manufacturing process of a display apparatus has been difficult. On the other hand, in this embodiment, the protrusions 24 having the side wall 28p that is perpendicular to the desired pretilt direction are arranged with sufficient intervals. As a result, the pretilt is controlled using an orientation defect formed near the side wall 28p. Therefore, unlike the configuration disclosed in Patent Document 5, there is no need to control the shape with an extremely high degree of accuracy. In addition, as long as the shape of the upper surface of the protrusion 24 has a linear portion and prescribed symmetry, a desired pretilt can be obtained even when the shape of the protrusion 24 is rounder than the designed shape (referred to as “shape imprecision”). Therefore, manufacturing using an exposure apparatus (resolution: at least 0.5 μm but no more than 1.0 μm, for example) that is normally used in a manufacturing process of a display apparatus becomes possible.

The configuration disclosed in Patent Document 4 is also based on a principal that is completely different from that of orientation control in this embodiment. None of the plurality of protrusions (posts) disclosed in Patent Document 4 has an upper surface that meets the requirements of the ratio W_{Y}/L and symmetry. Therefore, liquid crystal cannot be oriented in a prescribed direction based on the principle explained above with reference to FIG. 8.

(1) Examining Various Parameters of the Alignment Control Structure

The inventor of the present invention found that controlling the parameters shown in table 1 is important in order to obtain a desired pretilt based on the aforementioned orientation principle. Each parameter is explained in detail below.

TABLE 1

| | | | | Arrangement |
|---|---|---|---|---|
| | Shape | | | Ratio of |
| | Anisotropy | | | arrangement |
| | of | | | pitch P and |
| | the upper | Tilt angle of | Area ratio of | height H of |
| | surface | side wall | protrusions | the protrusion |
| Parameters | shape W_{Y}/L | γ (°) | (%) | H/P |
| Appropriate | At least 1.6 | At least 70° | At least 15% | At least 0.15 |
| range | No more | No more | No more | No more |
| | than 2.5 | than 95° | than 30% | than 0.2 |

Tilt Angle of the Side Wall of the Protrusion 24 (Taper Angle) γ

In order to achieve the orientation principle shown in FIG. 8, the liquid crystal orientation needs to be confined near the side wall 28p of the protrusion 24. In order to do this, it is preferable to control the tilt angle (taper angle) γ of the side wall 28p relative to the substrate surface to be an angle close to the right angle. Specifically, the tilt angle γ is preferably at least 70° but no more than 95°, or more preferably, at least 75° but no more than 95°.

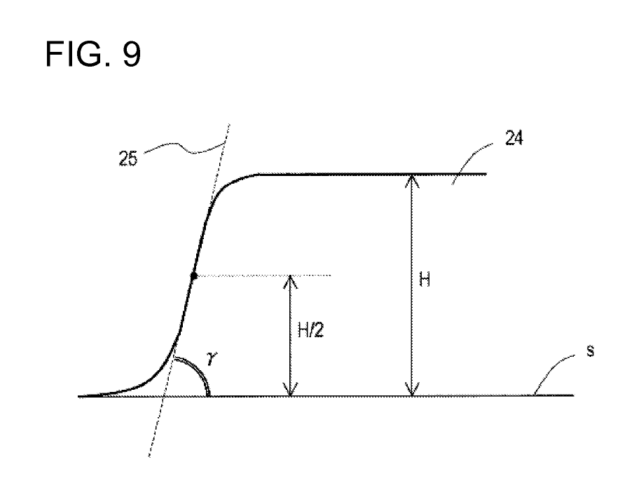

FIG. 9 is a magnified schematic cross-sectional view of the protrusion 24 to explain the tilt angle γ in the present invention. As shown in the figure, there may be a case in which the side wall of the protrusion 24 does not have a flat surface and becomes rounded in a part close to the bottom surface s of the protrusion 24. Even in such a case, in a cross-section vertical to the substrate, an angle formed by a plane 25 that includes a point that is half the height H of the protrusion 24 on the side wall relative to the bottom surface s of the protrusion 24 is referred to as a tilt angle γ.

When each protrusion 24 is formed of a columnar structure made of a resin material and a vertical alignment film (polyimide film, for example) formed thereon, the tilt angle γ is primarily determined by the tilt angle of the side wall of the columnar structure and the thickness and forming method of the vertical alignment film.

A protrusion having a minimum line width of 0.8 μm was formed, and a relation between the tilt angle γ of the side wall of the protrusion 24 and the tilt angle of the side wall of the columnar structure that becomes a foundation was examined. The relation is explained below.

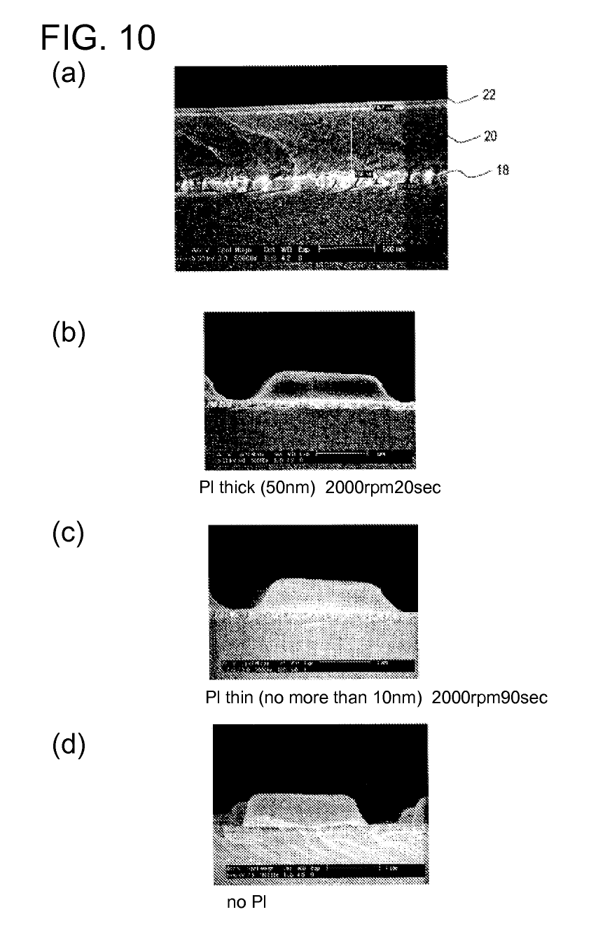

FIG. 10(a) is an image showing a cross-sectional SEM image that shows a portion of the protrusion, and FIG. 10(b) is a side view of the single protrusion. In this example, a 127 nm-thick electrode layer (here, an ITO film) 18, a resin layer 20 having the 590 nm-thick columnar structure, and an approximately 50 nm-thick vertical alignment film (here, a polyimide film) 22 are formed on a glass substrate. The vertical alignment film 22 is formed by spin coating application (rotation speed 2000 rpm, 20 sec) followed by baking (180° C., 60 min). As seen in FIG. 10(b), the tilt of the side wall of each protrusion 24 becomes gentler as it approaches the glass substrate. The tilt angle γ of the side wall of these protrusions 24 is approximately 60°.

Also, a cross-sectional SEM image of the protrusion 24 when the vertical alignment film 22 of no more than 10 nm in thickness has been formed is shown in FIG. 10(c). This vertical alignment film 22 is formed by spin coating application (rotation speed 2000 rpm, 90 sec) on the resin layer 20 followed by baking (180° C., 60 min). As shown in FIG. 10(c), when the vertical alignment film 22 becomes thin, the tilt of the side wall becomes about constant. Furthermore, the tilt angle γ of the side wall is approximately 70°, and is larger than the angle γ shown in FIG. 10(b).

For comparison, FIG. 10(d) shows a side view of the columnar structure when only the resin layer 20 formed of the columnar structure has been formed on the ITO film 18 and the vertical alignment film 22 has not been applied or baked. As shown in the figure, the side wall of each columnar structure of the resin layer 20 is nearly flat. The tilt angle of the side wall to the substrate surface is approximately 79°, and is larger than the tilt angle γ of the side wall of the protrusion 24 shown in FIG. 10(b).

From these results, it can be concluded that the tilt angle γ of the side wall of the protrusion 24 can be controlled to be within the preferable range by controlling the tilt angle of the side wall of the columnar structure of the resin layer 20 and by adjusting the thickness of the vertical alignment film 22. For example, in order to adjust the tilt angle γ of the side wall of the protrusion 24 to be at least 70° but no more than 95°, it is preferable to control the tilt angle of the side wall of the columnar structure formed in the resin layer 20 to be at least 75° but no more than 95°. More preferably, it is controlled to be at least 80° but no more than 95°. The tilt angle of the side wall of the columnar structure can be controlled by the material of the resin layer 20, exposure conditions, the size and the shape of the unit pattern, and the like. If the tilt angle of the columnar structure of the resin layer 20 is within the aforementioned range, the tilt angle γ becomes at least 70° but no more than 95° (at least 70° and less than 90°, for example), although it depends on the thickness of the vertical alignment film 22.

The tilt angles γ of the protrusion 24 at the respective side walls 28p, 29p and 29q typically are about the same, but there may be a case in which the tilt angle γ at the side wall 28p is different from the tilt angles γ at the side walls 29p and 29q depending on the interval between the neighboring protrusions 24 and the shape of the upper surface of the protrusion 24. In such case, as long as the tilt angle γ at the side wall 28p is within the aforementioned range, an orientation defect can be easily formed near the side wall 28p, and orientation control can be performed more certainly. More preferably, the tilt angles γ at side walls 28p, 29p and 29q are all at least 70°. As a result, a larger pretilt angle can be formed.

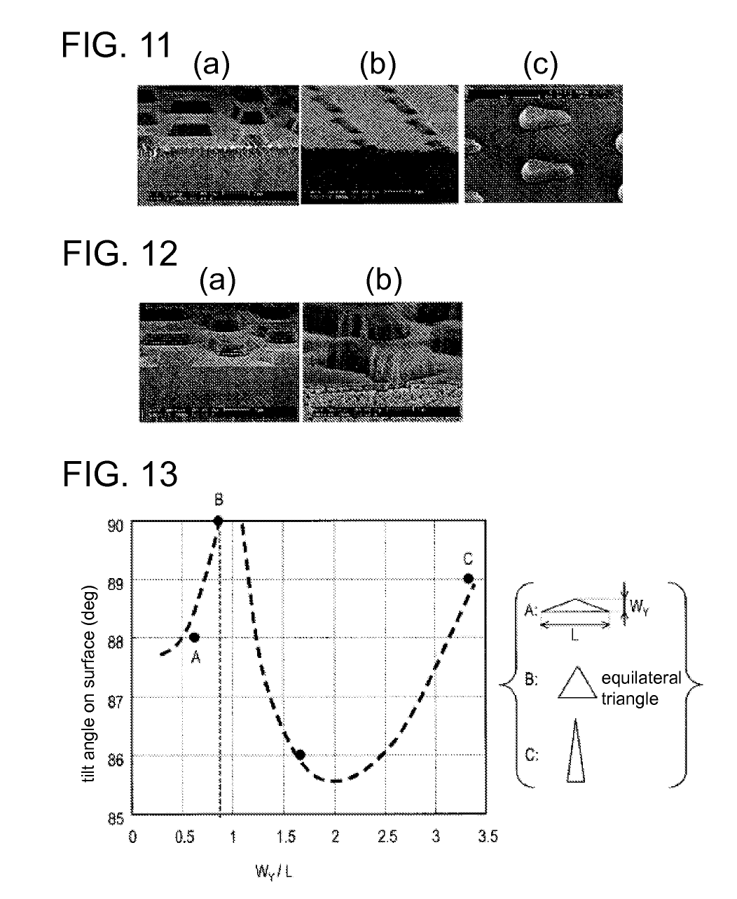

FIG. 11(a) to FIG. 11(c), FIG. 12(a), and FIG. 12(b) are images illustrating samples of various alignment control bodies in this embodiment. In the alignment control body shown in FIG. 11(a) to FIG. 11(c), the tilt angles γ are smaller than 70°. On the other hand, in the alignment control body shown in FIG. 12(a) and FIG. 12(b), the tilt angles γ are at least 80° but no more than 90, and liquid crystal orientation can be controlled more certainly than the alignment control bodies shown in FIG. 11(a) to FIG. 11(c).

W_{Y}/L

In order to tilt liquid crystal molecules in the direction Y (pretilt direction) by the aforementioned orientation principle, W_{Y}/L, which is the ratio of the length (maximum length) W_{Y} in the direction Y on the upper surface of the protrusion 24 to the length L (FIG. 7(b)) of the linear portion, needs to be controlled to be within a prescribed range. On the other hand, if the ratio W_{Y}/L is not within the prescribed range, there may be cases in which the pretilt direction cannot be set to one specific direction.

FIG. 13 is a graph illustrating a relation between W_{Y}/L of the upper surface of the protrusion 24 and the tilt angle θ that can be obtained by such protrusion 24. When the upper surface of the protrusion 24 is an equilateral triangle, W_{Y}/L is 0.866 (=√3/2) (point B). When the upper surface of the protrusion 24 is an isosceles triangle that is longer in the direction X, W_{Y}/L is below 1 (point A). When the upper surface of the protrusion 24 is an isosceles triangle that is longer in the direction Y, W_{Y}/L is larger than 1 (point C).

W_{Y}/L in this graph is a design value, and corresponds to the ratio W_{Y}/L in a light-shielding part of the exposure mask, for example. In reality, W_{Y}/L of the protrusion 24 becomes 10 to 20% larger than the design value shown in the graph because shape imprecision occurs depending on a resolution.

The tilt angle θ of the vertical axis in the graph is the tilt angle of liquid crystal molecules (interfacial liquid crystal molecules) near the upper surface of the protrusion 24 to the surfaces of the substrates 1 and 2. Therefore, when the protrusions 24 are provided only on the substrate 1, the pretilt angle of middle liquid crystal molecules becomes approximately half the pretilt angle (=90°−θ) of interfacial liquid crystal molecules.

As shown in FIG. 13, the tilt angle θ becomes approximately 90° when the upper surface of the protrusion 24 has a shape of an equilateral triangle or a shape close to an equilateral triangle because liquid crystal molecules cannot be oriented in a specific direction effectively. Thus, the pretilt cannot be obtained. If the upper surface of the protrusion 24 is in a shape of an isosceles triangle that is longer in the direction X (the triangle of point A, for example), two orientation directions are formed by two opposite sides respectively. Because these orientation directions are opposite to each other along the direction X (bilateral symmetry), the left and right orientations cannot be differentiated. As a result, two orientation directions coexist in one pixel, and there is a risk of display characteristics lowering. If the upper surface of the protrusion 24 becomes longer in the direction Y in a manner similar to the needle shape (the triangle of point C, for example), two orientation directions may occur along the direction Y. These orientation directions become mutually reversed along the direction Y, and the up and down orientations cannot be differentiated. As a result, two orientation directions coexist in one pixel, and there is a risk of display characteristics lowering.

Based on the results shown in FIG. 13, it can be concluded that in order to form a pretilt in a prescribed direction, the design value of W_{Y}/L of the unit pattern corresponding to the upper surface of the protrusion needs to be more than 1 and less than 3.3 when the mask is designed. As described above, after exposure and development processes have been performed, W_{Y}/L of the protrusion 24 that is actually formed becomes approximately 10 to 20% larger than W_{Y}/L of the unit pattern. Therefore, a pretilt in a prescribed direction can be formed if W_{Y}/L of the protrusion 24 is more than 1 but less than 3.5.

Preferably, the design value of W_{Y}/L is set to be at least 1.6 but no more than 2.0. As a result, interfacial liquid crystal molecules can be tilted by more than 4° (=90°−θ) from the normal line to the substrate, and a pretilt can be formed more effectively. Therefore, a preferred range of W_{Y}/L of the protrusion 24 that is actually formed is at least 1.6 but no more than 2.5.

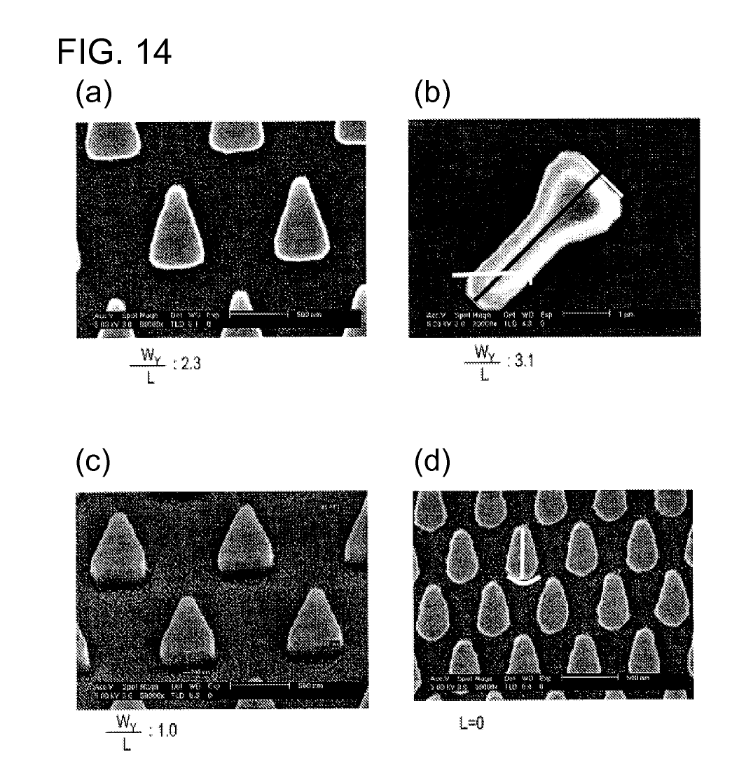

In order to further confirm the relation shown in FIG. 13, a plurality of alignment control body samples with different W_{Y}/L were prepared, and whether or not a pretilt could be obtained was examined. FIG. 14(a) to FIG. 14(c) are images showing alignment control body samples in which protrusions have been formed. These alignment control body samples have the following ratios respectively: W_{Y}/L=2.3, W_{Y}/L=3.1, and W_{Y}/L=1.0. FIG. 14(d) is an image showing the alignment control body sample in which each protrusion does not have a linear portion L.

Liquid crystal cells were formed using these alignment control body samples. It was confirmed that middle liquid crystal molecules had a pretilt in liquid crystal cells using the alignment control body samples shown in FIG. 14(a) and FIG. 14(b).

The protrusion of FIG. 14(b) has the upper surface that is roughly in a triangular shape. This was formed using an exposure mask having a T-shaped unit pattern. Thus, even when a desired shape set by a unit pattern was not obtained for the protrusion, a pretilt was generated as long as W_{Y}/L was more than 1 and less than 3.5.

On the other hand, in a liquid crystal cell using the alignment control body sample (W_{Y}/L=1.0) shown in FIG. 14(c), the prescribed pretilt was not formed in the middle liquid crystal molecules. As described above with reference to FIG. 13, it can be considered that this was because the direction of the pretilt could not be set to one specific direction.

Also, in a liquid crystal cell using the alignment control body sample (L=0) shown in FIG. 14(d), the prescribed pretilt was not formed in the middle liquid crystal molecules. It can be considered that this was because the linear portion L has not been formed on the contour of the upper surface of the protrusion due to shape imprecision. The orientation defect cannot be formed near the side wall of the protrusion unless the linear portion L is formed.

In this embodiment, it is preferable to design an exposure mask for patterning the resin layer so that W_{Y}/L becomes the aforementioned prescribed value by taking into account shape imprecision due to the resolution of the exposure apparatus, material of the resin layer, and the like.

Area Ratio of Protrusions

The amount of the pretilt varies depending on the arrangement pitch and the height H of the protrusions 24. However, the minimum value of the arrangement pitch largely depends on the resolution of the exposure apparatus used and the material of the resin layer, and cannot be selected flexibly. Also, the range of the height H of the protrusion 24 depends on the material of the resin layer. Therefore, in this embodiment, the amount of the pretilt is controlled by an area ratio of the region where the plurality of protrusions 24 have been formed to the overall surface in contact with the vertical alignment liquid crystal layer viewed from the direction normal to the substrate (hereinafter simply referred to as an “area ratio of protrusions”).

For example, in a plan view shown in FIG. 7(a), assuming that the area of the overall surface in contact with the liquid crystal layer is S₁, and the total area of the plurality of the protrusions 24 is S₂₄, and the total area of the region 26 where the protrusions 24 have not been formed on the surface adjacent to the liquid crystal layer is S₂₆, the area ratio of the protrusions is S₂₄/S₁(=S₂₄/(S₂₄+S₂₆)).

When the electrode layer 18 is formed on the substrate side (opposite side from the liquid crystal layer 14) of the protrusions 24, a smaller area ratio of protrusions is favorable from a perspective of the voltage drop. However, if the area ratio of protrusions is too small, the effects to pretilt liquid crystal molecules may be reduced. Furthermore, when the arrangement pitch is constant, the area ratio of protrusions is restricted due to the limit of the height H and of the line width (resolution) of protrusions in the manufacturing process, and cannot be made arbitrarily small. The minimum value of the area ratio of protrusions varies depending on the manufacturing process and the arrangement pitch. However, it is preferable to be at least 15% assuming that the arrangement pitch is 1 to 5 μm, for example.

In order to achieve the orientation principle of this embodiment, the area ratio of protrusions needs to be limited to no more than 30%. In the orientation principle of this embodiment, as described with reference to FIG. 8, the liquid crystal orientation is controlled by the side walls 28p, 29p, 29q of the protrusions 24 and the bottom surface of the recess, and it is required to keep a sufficient interval between the neighboring protrusions 24. As the area ratio of protrusions becomes more than 30%, the interval between the neighboring protrusions 24 becomes smaller, and side walls of the neighboring protrusions (referred to as “other walls”) get closer to the respective side walls 28p, 29p, and 29q (FIG. 8(b)) of the protrusions 24. Therefore, liquid crystal orientations near the respective side walls 28p, 29p, and 29q become susceptible to the effect of the other side walls. As a result, there is a risk that a prescribed orientation direction cannot be obtained. When the area ratio of protrusions exceeds 50%, distances between other walls and the side walls 28p, 29p, and 29q become even smaller, and liquid crystal orientations near the side walls 28p, 29p, and 29q are controlled to be nearly parallel to the substrate surface by the side walls 28p, 29p, and 29q, as well as by the other walls. Thus, the liquid crystal orientation is confined on the bottom surface (plane surface) of the recess. As a result, liquid crystal molecules tilt to the opposite direction from the direction of this embodiment because of the shape of the bottom surface of the recess. Such liquid crystal orientation would be similar to the liquid crystal orientation of Patent Document 5 that was explained with reference to FIG. 3.

In this embodiment, the height H of the protrusion is preferably approximately 0.5 μm because of the relation to the arrangement pitch that will be explained later. When the height H of the protrusion is 0.5 μm and the arrangement pitch of protrusions is constant (1 to 5 μm), the area ratio of protrusions is preferably controlled to be approximately no more than 20% in order to limit the voltage drop to the level approximately similar to the vertical alignment film (thickness: 100 nm, for example). As described, the liquid crystal orientation can be controlled with more certainty when the area ratio of protrusions is appropriately selected by taking into account the height H of protrusions and the thickness of the vertical alignment film.

If the area ratio of protrusions becomes too large, the desired pretilt cannot be obtained. The reason for this is explained here with reference to two-dimensional simulation results.

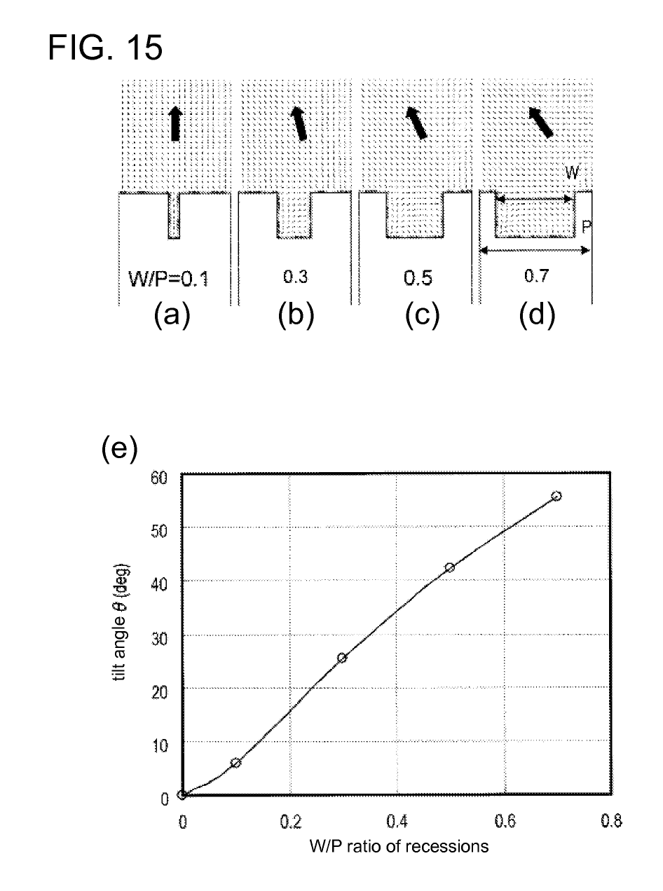

FIG. 15(a) to FIG. 15(d) are simulation results showing changes of the pretilt according to the ratio of the width W of the recess (the region where the protrusions were not formed) to the arrangement pitch P. FIG. 15(e) is a graph showing the simulation results shown in FIG. 15(a) to FIG. 15(d). In this simulation, the liquid crystal orientation (liquid crystal orientation that is tilted with respect to the normal line to the substrate) by the left side wall and the bottom surface is formed at the lower left of the recess, and the orientation state of the overall liquid crystal layer is obtained. Based on the simulation results, if the ratio W/P, which is the ratio of the width of the recess to the arrangement pitch P, is small, the liquid crystal orientation at the lower left of the recess is confined in the recess and, and cannot be communicated in the thickness-direction of the liquid crystal layer. As the ratio W/P becomes larger, effects of the liquid crystal orientation at the lower left of the recess become greater. Based on the graph in FIG. 15(e), it can be said that the tilt angle of the middle liquid crystal molecules becomes larger nearly in proportion to the ratio W/P. In other words, it can be said that if the arrangement pitch is constant, the smaller the ratio of protrusions is, the bigger the pretilt can become. Here, because this simulation is a two-dimensional simulation, the numerical value of the tilt angle (tilt angle of the interfacial liquid crystal molecules) θ is different from the actual numerical value.

When the protrusions 24 shown in FIG. 7(b) are formed using an exposure apparatus, the area ratio of protrusions may be controlled by the pattern of the mask used when the resin layer 20 (FIG. 4) undergoes exposure.

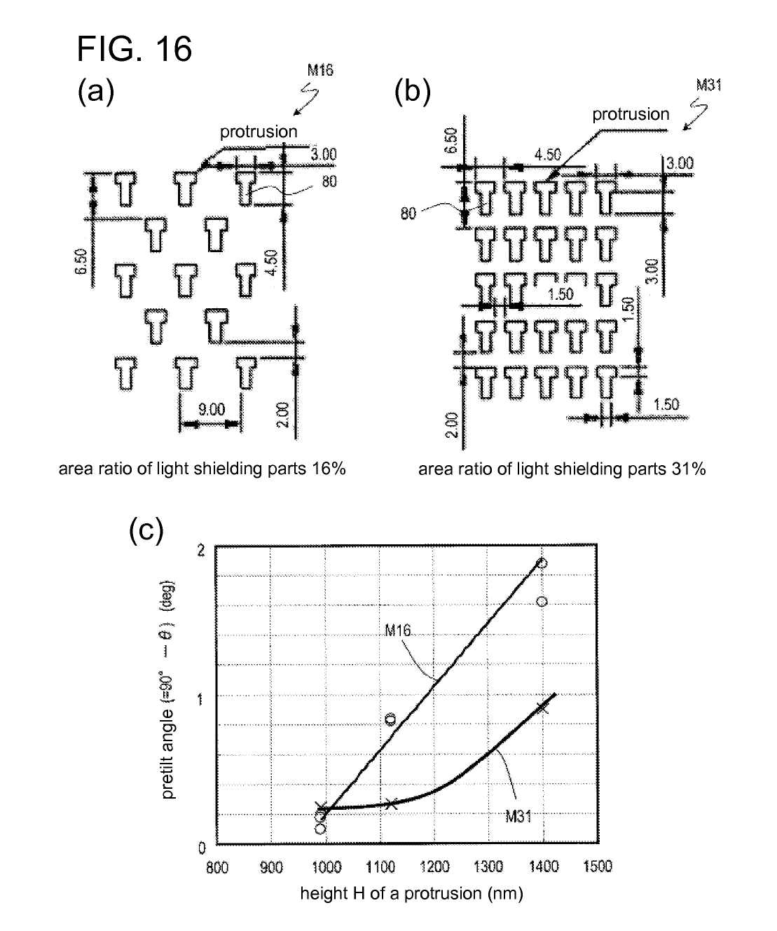

FIG. 16(a) and FIG. 16(b) are plan views illustrating mask patterns, respectively. As shown in the figure, when the resin layer 20 is formed using a positive resist material, respective masks M16 and M31 have light shielding parts 80 corresponding to protrusions. The arrangement pitch of light shielding parts 80 is 6.5 μm in both masks M16 and M31. The unit of numerical values shown in the figure is μm. Assume that the total area of light shielding parts 80 corresponding to protrusions in masks M16 and M31 is Sm. Then, the aforementioned S₂₄ is roughly equal to Sm, or becomes Sm>5₂₄. Generally, because light is diffracted at the periphery of the light shielding parts of the masks during exposure, the shape of the upper surface of the protrusion 24 becomes rounder and slightly smaller than the shape of the light shielding part of the mask. The area ratios Sm/S₁ (hereinafter simply referred to as “area ratios of light shielding parts”) of the light shielding parts in the masks M16 and M31 are 16% and 31% respectively. Therefore, when the protrusions 24 are formed using the mask M16 or M31, the area ratio of protrusions becomes slightly smaller than 16% and 31%, respectively. The area ratio of protrusions formed using the mask M16 is 14%, for example, and the area ratio of protrusions formed using the mask M31 is 27%, for example.

Protrusions 24 with different heights H were formed using the masks M16 and M31, and the tilt angles θ formed by these protrusions 24 were examined. The results are shown in FIG. 16(c). From these results, it was found that an alignment control structure that can pretilt liquid crystal molecules in a prescribed direction can be obtained using either mask M16 or mask M31.

Also, based on the results shown in FIG. 16(c), it can be said that the sample using the mask M16 having the area ratio of light shielding parts of 16% forms a larger pretilt. Here, the pretilt angle (°) is the angle of interfacial liquid crystal molecules with respect to the normal line to the substrate, and is equal to 90°−θ (θ: tilt angle).

When the area ratio of light shielding parts is 16%, i.e., when the area ratio of protrusions is approximately 14 to 16%, it is easier to control the liquid crystal orientation by two side walls of the protrusion that face each other and by the nearby bottom surface. On the other hand, when the area ratio of light shielding parts is increased to 31%, i.e., when the area ratio of protrusions is increased approximately to 27 to 31%, it can be said that it becomes difficult to obtain the aforementioned liquid crystal orientation because a part of liquid crystal orientation is confined between the plurality of neighboring protrusions (recess). Especially, when the height H of protrusions 24 becomes large, it can be said that, compared to the pretilt angle formed using the mask M16, the difference between the pretilt angles becomes greater because it becomes easier for the liquid crystal orientation to be confined in recesses. Although not shown in the figure, when the area ratio of protrusions becomes larger than 31%, it becomes even more difficult to obtain the liquid crystal orientation according to the aforementioned principle, and the pretilt angle becomes smaller.

Arrangement Pitch P of Protrusions and Height H of Protrusion

Arrangement Pitch P

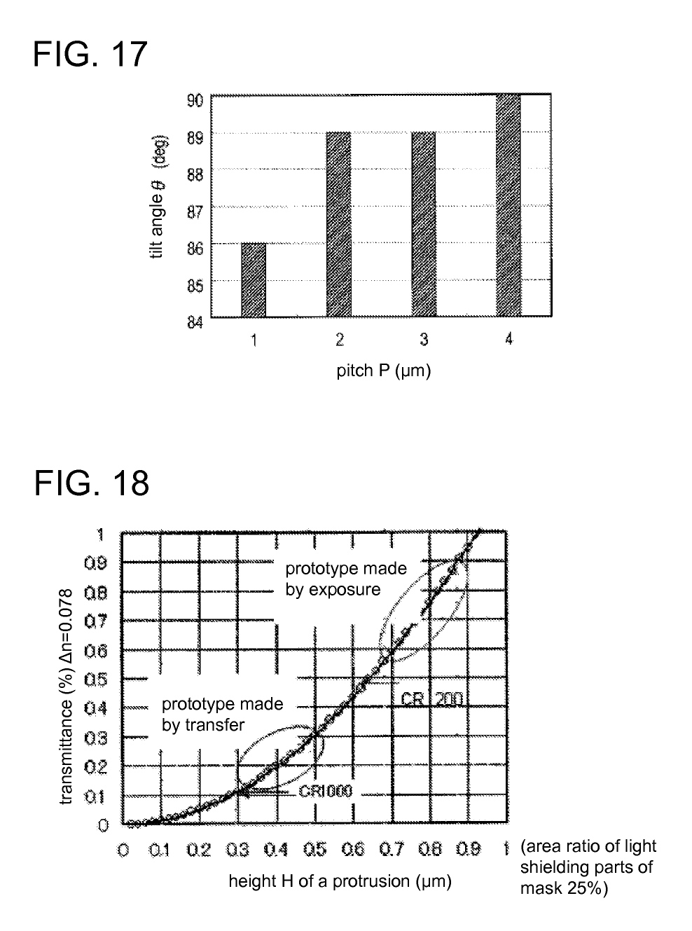

FIG. 17 is a graph showing a relation between the arrangement pitch P of protrusions 24 and the tilt angle θ. Based on FIG. 17, it can be said that if the area ratio of protrusions as well as the ratio W_{Y}/L and the height H of the respective protrusions 24 do not change, the smaller the arrangement pitch is, the larger the pretilt (90°−θ) becomes. Furthermore, based on the results of another experiment by the inventor of the present invention, it has been found that reduction in display contrast can be prevented by making the respective protrusions finer. Therefore, the smaller arrangement pitch is preferred.

However, as described above, the arrangement pitch is restricted by the manufacturing process. It largely depends on the resolution (0.5 to 1.0 μm, for example) of the exposure apparatus used and on the material of the resin layer, and cannot be selected flexibly. If the arrangement pitch becomes too small relative to the resolution, shape imprecision becomes quite significant, and a prescribed pretilt cannot be formed.

In this embodiment, as discussed later, the pattern of the upper surface of the protrusion is designed by using, as a unit, a square having a side that has the same length as the resolution. In this case, the arrangement pitch needs to be no less than four times the length of the resolution. The arrangement pitch preferably is no less than four times and no more than six times the resolution. For example, when an exposure apparatus with a 0.8 μm resolution is used, the arrangement pitch is approximately 3 to 5 μm.

Height H of Protrusions

When the arrangement pitch is within the aforementioned range, display contrast changes based on the height H of the protrusions 24 if the area ratio of protrusions and W_{Y}/L of the respective protrusions are unchanged.

FIG. 18 is a graph illustrating a relation between the height H of the protrusions 24 and the transmittance (leaked light). Here, the area ratio of light shielding parts of the mask is 25%, and that the arrangement pitch is 3 μm, and that Δn (transmissivity) of the liquid crystal layer is 0.078. When contrast is calculated based on these results, it can be said that the smaller the height H is, the higher display contrast becomes, and that display contrast becomes 1000:1 when the height H is 0.3 μm. Therefore, in order to ensure display contrast, the height H of the protrusions 24 preferably is no more than 0.7 μm. If the height H of the protrusions 24 is approximately 0.7 to 1 μm, prototypes of the protrusions 24 can be made by photolithography (exposure). However, if the height H is approximately 0.5 μm or less, prototypes of protrusions 24 are preferably made by transfer.

In order to control the liquid crystal orientation with more certainty based on the aforementioned orientation principle, it is preferable to control the ratio H/P, which is the ratio of the height H to the arrangement pitch P, to be within a prescribed range. Here, because the arrangement pitch is determined roughly by the resolution of the exposure apparatus, it is required to appropriately select the height H in order to obtain the prescribed H/P.

When the ratio of the height H of the protrusions 24 to the arrangement pitch P becomes too large, the liquid crystal orientation becomes more likely to be confined in recesses between the plurality of neighboring protrusions, and the desired pretilt cannot be obtained. Therefore, it is preferable to set the height H so that H/P becomes 0.2 or less. On the other hand, when the ratio of the height H of the protrusions 24 to the arrangement pitch P becomes too small, there is a risk that the liquid crystal orientation cannot be confined near the side wall 28p of the protrusions. Therefore, it is preferable to set the height H so that H/P becomes 0.15 or higher. If the arrangement pitch P_{X} in the direction X and the arrangement pitch P_{Y} in the direction Y are both 3 to 4 μm, it is preferable to set the height H to be at least 0.45 μm but no more than 0.8 μm. The height H is preferably set at 0.5 μm, for example.

The arrangement pitch P_{X} in the direction X and the arrangement pitch P_{Y} in the direction Y may be different. In that case, it is sufficient if the height H to the arrangement pitch P_{X} in the direction X is preferably at least 0.15 but no more than 0.2. However, both arrangement pitches P_{X} and P_{Y} are preferably within the aforementioned range. As a result, the prescribed pretilt can be achieved while preventing display contrast from decreasing.

In this embodiment, the shape of the upper surface, the height H, the size, the arrangement of the protrusions, and the like are appropriately adjusted such that the parameters shown in the table 1 are all in appropriate ranges with respect to the manufacturing method of the alignment control body and the apparatus used in manufacturing. Specifically, it is preferable to obtain the optimum combination of the aforementioned parameters for the resolution used during manufacturing.

When an exposure apparatus (stepper) having a 0.5 to 1.0 μm resolution is used, the optimum combination is the following, for example: (I) 0.5 μm for the height H of the protrusions; 3 μm for the arrangement pitches P_{X} and P_{Y} in the directions X and Y, respectively; and 13% for the area ratio of the protrusions. In addition, it is desirable to set the tilt angle γ of the side wall of the protrusion to be 70° or higher, and W_{Y}/L to be at least 1.6 but no more than 2.5. When a higher resolution (approximately 0.3 μm, for example) is available, the optimum combination is the following, for example: (II) 0.3 μm for the height H of the protrusions; 1.5 μm for the arrangement pitches P_{X} and P_{Y} in the directions X and Y; and 25% for the area ratio of protrusions. In addition, it is desirable to set the tilt angle γ of the side wall of the protrusion to be 70° or higher, and W_{Y}/L to be at least 1.6 but no more than 2.5. In order to make the structure actually manufactured meet these parameter requirements, the mask needs to be designed by taking into account shape imprecision caused by the manufacturing process.

Examples of Appropriate Parameter Combinations Studied

Parameters shown in table 1 are mutually related. Therefore, in order to optimize the alignment control structure in this embodiment, it is important to find a more preferable combination of parameters in addition to setting these parameters to be within the respective prescribed ranges.

Explained below is one example in which the relation between the arrangement pitch P and the ratio W_{Y}/L on the upper surface of the protrusion as well as a preferable combination of these parameters were studied.

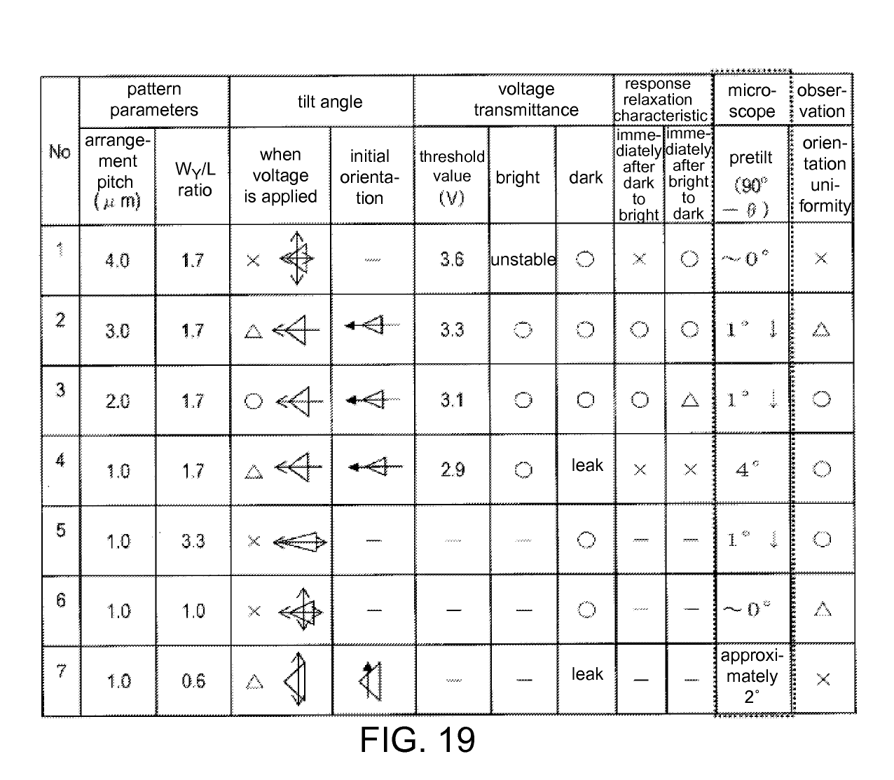

FIG. 19 is a table showing results illustrating changes of the pretilt when the ratio W_{Y}/L on the upper surface of the protrusion 24 was constant and the arrangement pitch was changed, as well as changes of the pretilt when the arrangement pitch was constant and the ratio W_{Y}/L was changed. The height H of the protrusion 24 was 150 nm. Here, samples having the ratios W_{Y}/L and the arrangement pitches shown in the table were manufactured using an EB drawing machine, and changes of the pretilt in each sample were studied.

Based on the results, it can be said that when the ratio W_{Y}/L on the upper surface of the protrusion 24 is constant, if the arrangement pitch is smaller, the pretilt angle of the interfacial liquid crystal molecules is larger, and a uniform orientation can be obtained (No. 1 to 4). If the arrangement pitch is too large, it can be said that it becomes more difficult to orient liquid crystal molecules in a prescribed direction. Here, it was not possible to orient liquid crystal molecules in the prescribed direction when the arrangement pitch was 4 μm. However, the maximum value of the arrangement pitch varies depending on the shape of the protrusion 24, the height H, and the like.

Meanwhile, when the arrangement pitch is constant, the pretilt changes depending on the ratio W_{Y}/L on the upper surface of the protrusion 24 (No. 4 to 7). When W_{Y}/L is 1.0 (No. 6), the azimuthal direction of liquid crystal molecules cannot be controlled. When W_{Y}/L is below 1 (No. 7) or when W_{Y}/L is high at 3.3 (No. 5), liquid crystal molecules are oriented along one of the two directions that are opposite to each other. As a result, liquid crystal molecules cannot be oriented in one prescribed direction.

Based on the results, it can be said that the combination having the arrangement pitch: 1.0 μm and W_{Y}/L: 1.7 (No. 4) is one of the appropriate combinations.

(2) Method for Manufacturing the Alignment Control Body

Next, an example of a method for manufacturing an alignment control body of this embodiment is explained.

(A) Manufacturing Method by Photolithography (Exposure)

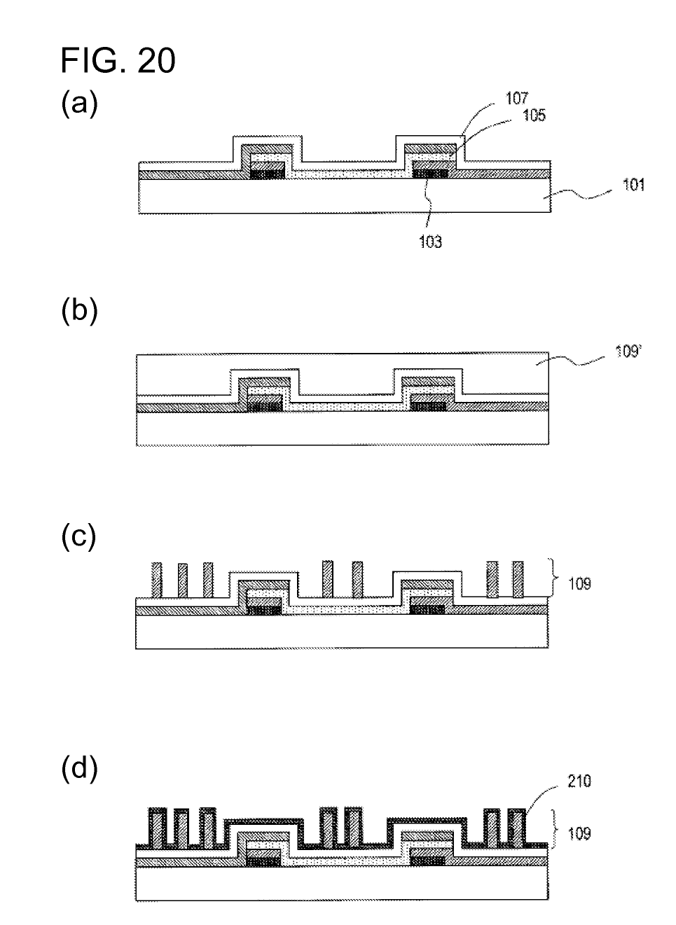

FIG. 20(a) to FIG. 20(d) are schematic cross-sectional views showing process steps to explain a method for manufacturing the alignment control body in this embodiment. Here, a process of forming the alignment control structure having a plurality of protrusions on a color filter (CF) substrate by photolithography is explained as an example.

First, a CF substrate shown in FIG. 20(a) is prepared. The CF substrate can be obtained by forming a black matrix 103, a color filter 105, and a transparent conductive film (an ITO film, for example) 107 on a glass substrate (thickness: 0.7 mm) 101 using a known method.

Next, as shown in FIG. 20(b), a resin layer (photoresist layer) 109′ is formed by applying a photosensitive resin material by spin coating (1000 rpm, 10 sec) on the ITO film 107 and by baking it. In this embodiment, a positive resist material (HRC series manufactured by JSR Corporation) that is an acrylic resin is used as the resin material. Baking is performed by hot plate baking (100° C., 90 sec), for example.

Next, exposure of the resin layer 109′ is performed in a large stepper (resolution: 0.8 μm, for example) using an exposure mask (not shown in the figure). A mask having a plurality of arranged light shielding parts that have shapes corresponding to the upper surfaces of the protrusions is used as the exposure mask. Then, development is performed using a TMAH (tetramethylammonium hydroxide) developing solution (TMAH concentration: 1.0 wt %). Developing time is 100 seconds. As a result, parts that were shielded from light by the light shielding parts of the exposure mask and that did not undergo exposure are removed. Then, the resin layer 109′ is baked in a clean oven (200° C., 60 min), and a resin layer 109 that is formed of a plurality of columnar structures is obtained as shown in FIG. 20(c). The thickness of the resin layer 109, in other words, the height of each columnar structure is 500 nm, for example. Next, although not shown in the figure, a photospacer is formed by a known method.

Then, as shown in FIG. 20(d), a vertical alignment film (thickness: 50 nm) 210 is applied on the resin layer 109. Here, the vertical alignment film 210 is formed by applying a soluble polyimide film (JALS series) by spin coating (2000 rpm, 20 sec) and then by baking (180° C., 60 min) it in a clean oven. The alignment control body is obtained this way.

Although the alignment control structure was formed on the CF substrate in the aforementioned method, it may be formed on a TFT substrate. In that case, according to a known method, a pixel electrode is formed on a TFT substrate, and then the resin layer 109 is formed using a method similar to the aforementioned method explained with reference to FIG. 20(b) and FIG. 20(c). Then, the vertical alignment film 210 is formed using a method similar to the aforementioned method explained with reference to FIG. 20(d).

Although not shown in the figure, there is a case in which the color filter (CF) is not formed on the front substrate, and the TFT substrate having the CF thereon is used as the back substrate. Even in that case, the alignment control structure that is formed of a plurality of protrusions can be provided either on the TFT substrate having the color filter thereon or on the opposite substrate that is disposed to face the TFT substrate.

When the alignment control structure is formed on the opposite substrate, an ITO film that becomes the opposite electrode is applied on a glass substrate using a known method. Then, using a method similar to the aforementioned method explained with reference to FIG. 20(b) to FIG. 20(d), the resin layer 109 is formed on the ITO film, and a photospacer and the vertical alignment film 210 are formed. When the alignment control structure is formed on the TFT substrate having the color filter thereon, the resin layer 109 is formed using the similar method to the aforementioned method explained with reference to FIG. 20(b) and FIG. 20(c) on the substrate on which TFTs, the CF, and the pixel electrode have been formed by a known method. Then, the vertical alignment film 210 is formed using a method similar to the aforementioned method explained with reference to FIG. 20(d).

The manufacturing method by photolithography is suitably applied when the alignment control structures are provided on a TFT substrate or on a TFT substrate having a CF thereon. This is because only one process of forming one layer (resin layer 109) is added to the conventional process, thereby manufacturing the alignment control body without significantly increasing manufacturing cost and manufacturing process. When the resin layer 109 is formed on a substrate having a CF thereon by photolithography, there may be a risk of damaging the CF.

(B) Manufacturing Method by Transfer

In the aforementioned method, patterning of the resin layer 109′ was performed by photolithography. However, patterning may be performed by transfer instead. The method for manufacturing the alignment control body by transfer is explained below.

First, a master having a recessed and projected pattern on its surface is prepared. The master can be obtained by forming a photoresist layer on a substrate and then by patterning the photoresist layer using a two-beam interference exposure apparatus, an electron beam drawing apparatus, or a mask exposure apparatus, such as a stepper. When the mask exposure apparatus is used, it is required to design the exposure mask so that the parameters shown in table 1 are within the appropriate ranges. Also, the master may be manufactured by mechanically carving a substrate made of a material such as Al and the like or by etching a monocrystalline substrate such as a Si substrate and the like. The master is not required to be optically transparent as long as it is made of a material that can be microfabricated. As the material that can be microfabricated, a high-resolution resist may be used, for example.

Next, the CF substrate shown in FIG. 21(a) is prepared. The CF substrate is obtained by forming a black matrix 103, a color filter 105, and a transparent conductive film (ITO film, for example) 107 on a glass substrate (thickness: 0.7 mm) 101 using a known method.

Next, as shown in FIG. 21(b), a resin layer 201 is obtained by applying a resin material on the ITO film 107 by spin coating (1000 rpm, 10 sec). In this embodiment, an ultraviolet curable resin (here, a diluted product of PAK-01 manufactured by Toyo Gosei Co., Ltd) is used as the resin material. The thickness of the resin layer 201 is 1000 nm.

Next, as shown in FIG. 21(c), a transfer resin layer 202 is obtained by transferring the surface pattern of the master 212 to the resin layer 201 using a UV press apparatus. Here, transfer pressure is 4 MPa; transfer time is 300 sec; and the UV irradiation amount for curing the resin material is 1 J/cm². The thickness of the recessed portion in the transfer resin layer 202 (thickness of the residual film) is 250 nm, for example.

Then, as shown in FIG. 21(d), a residual film 202R of the transfer resin layer 202 is removed by dry etching. In this way, a resin layer 203 having a plurality of columnar structures is obtained.

Next, as shown in FIG. 21(e), a vertical alignment film 210 is formed on the resin layer 203. The method for forming the vertical alignment film 210 is similar to the aforementioned method explained with reference to FIG. 20(d). The alignment control body is obtained this way.

When the resin layer 203 is formed by transfer, options for materials of the resin layer 203 increase because there is no need to use a highly photosensitive material as the material of the resin layer 203. As a result, a display apparatus having high performance and excellent reliability can be obtained.

When the alignment control structure is provided on a substrate having a recessed and projected pattern such as a TFT substrate and the like, it is difficult to apply the manufacturing method by transfer. Therefore, the manufacturing method by transfer can be suitably applied to cases in which the resin layer 203 is formed on a CF substrate as well as to cases in which the resin layer 203 is formed on the opposite substrate when a TFT substrate having a CF thereon is used. The method for forming the resin layer 203 on the opposite substrate is similar to the aforementioned method explained with reference to FIG. 21(a) to FIG. 21(c).

Transfer conditions in this embodiment are not limited to the conditions above. However, it is preferable to adjust the transfer conditions, particularly transfer pressure and pressure time, such that the thickness of the residual film (recess) is within the range 250 nm or less, or preferably 200 nm or less.

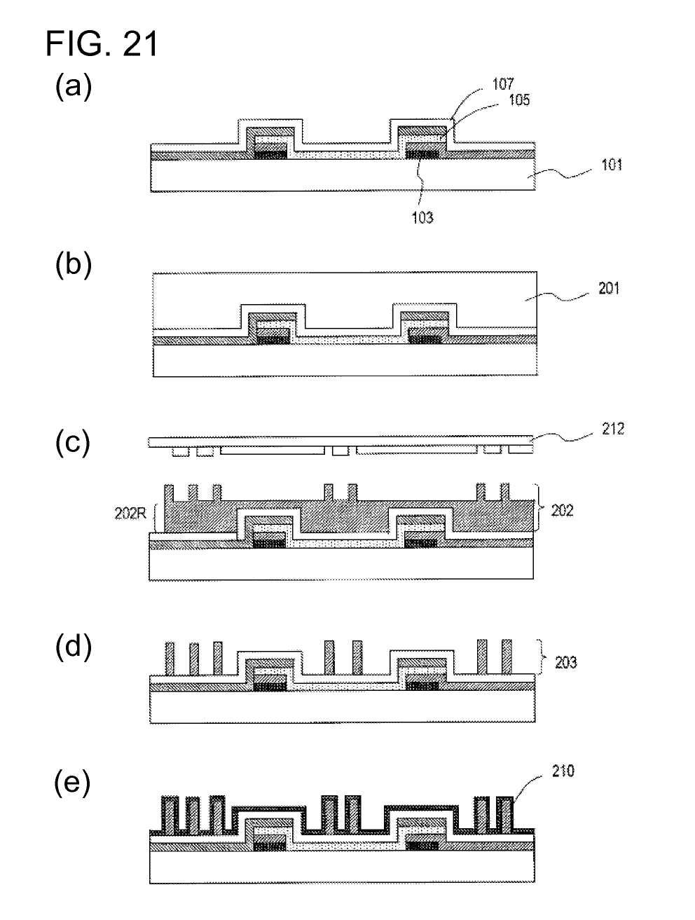

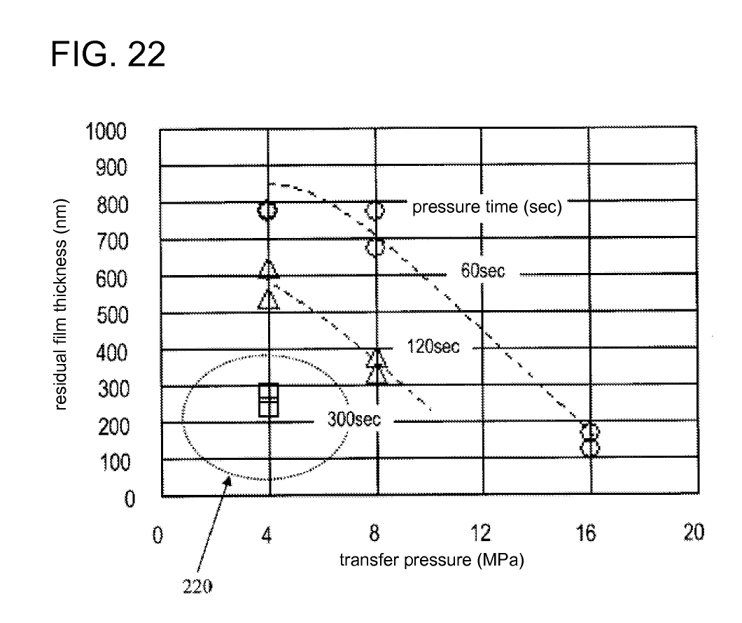

FIG. 22 is a graph showing the relation between the transfer pressure and the thickness of the residual film when a transfer is performed onto the resin layer (diluted product of PAK-01 manufactured by Toyo Gosei Co., Ltd, thickness: 1000 nm) 201 in this embodiment. Based on this graph, it can be said that the thickness of the residual film can be adjusted by controlling the transfer pressure and pressure time. The transfer pressure and the thickness of the residual film preferably are adjusted to be within the ranges shown by a dotted line 220 in this graph.

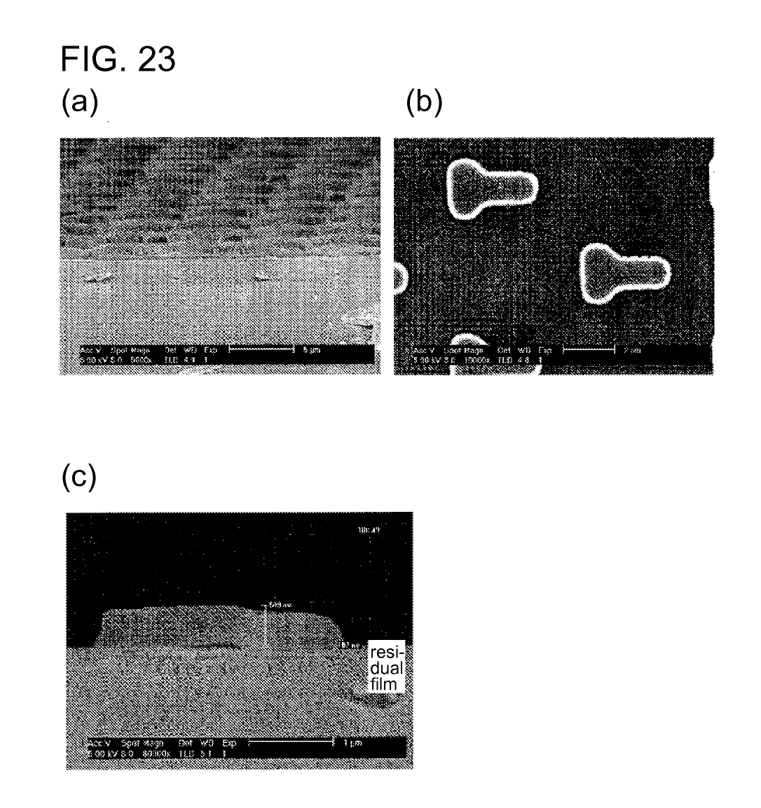

For example, assume that the transfer resin layer 202 is formed by performing a transfer onto the resin layer 201 when the transfer pressure is 4 MPa and pressure time is 300 sec. Then, the thickness of the residual film 202 R of the transfer resin layer 202 can become approximately 200 nm. FIG. 23(a) to FIG. 23(c) are an oblique perspective view, a top view, and a magnified cross-sectional view, respectively, illustrating a transfer resin layer 202. The thickness of the residual film shown in FIG. 23 (c) is 187 nm.

When the resin layer 203 is formed from the transfer resin layer 202 by the process shown in FIG. 21, the thinner the residual film on the resin layer 203 is, the more the effects of the voltage drop can be decreased. Because orientation performance is not affected even if there is no residual film, the thickness of the residual film on the resin layer 203 is preferably 0. Therefore, it is preferable to form high protrusions on the transfer resin layer 202, considering the thickness of the residual film 202R of the transfer resin layer 202, and perform etching on the transfer resin layer 202 until there is no resin layer 202R left. In this way, the resin layer 203 having no residual film can be formed.

The method by transfer is not limited to the method above. For example, it is possible to make a master in a roller-shape and to transfer the pattern on the side surface of the roller-shaped master onto the resin layer 201.

As described below, it is also possible to form a mask layer by transfer and to perform patterning of the resin layer using this mask layer. FIG. 24(a) to FIG. 24(e) are schematic cross-sectional views showing process steps to illustrate another method for forming the alignment control body by transfer.

First, a CF substrate shown in FIG. 24(a) is manufactured by a known method.

Next, as shown in FIG. 24(b), a transparent resin film (thickness: 1 μm) is applied on the CF substrate. By performing exposure and development on the resin film, an opening is formed on a part (terminal part) where a contact part is formed. Then, the resin film is cured and a resin layer 205 is formed. Alternatively, instead of the resin film, an inorganic film, such as SiO₂, SiN, or the like, may be used.

Next, as shown in FIG. 24(c), a resin for transfer is applied on the resin layer 205, and the surface pattern of the master 212 is transferred onto the transfer resin. The method for transferring is similar to the aforementioned method described with reference to FIG. 21(b). In this way, a transfer resin layer (thickness: 1 μm) 206 that becomes the mask layer is obtained on the resin layer 205.

Then, as shown in FIG. 24(d), using the ITO film 107 as an etch stop layer, the transfer resin layer 206 and a part of the resin layer 205 are removed by dry etching. In this way, a 1 μm-thick resin layer 207 that is formed of a plurality of protrusions is obtained. The respective protrusions are formed of the part of the resin layer 205 that has not been removed.

Next, as shown in FIG. 24(e), a vertical alignment film 210 is formed on the resin layer 207. The method for forming the vertical alignment film 210 is similar to the aforementioned method described with reference to FIG. 20(d). The alignment control body is formed this way.

Also, the method for forming the alignment control body in this embodiment is not limited to the method by (A) exposure or by (B) transfer. The alignment control body may be formed using an electron beam drawing apparatus, for example.

(C) Exposure Mask Design

Next, a method for designing a mask used for manufacturing the alignment control body of this embodiment is explained. The method for designing a mask explained here can be applied not only to designing of (A) an exposure mask that is used when the alignment control body is manufactured by photolithography, but also to designing of (B) an exposure mask that is used to manufacture a master when the alignment control body is manufactured by transfer.

In this embodiment, the mask is designed using a square as one unit. Each side of this square is the resolution r of the exposure apparatus used. In this specification, the unit of the square for design purposes is referred to as a “cell.” In this way, the smallest unit pattern that can be drawn with that resolution can be examined. Here, the unit pattern corresponds to the shape of the upper surface of the respective protrusions in the alignment control body.

In order to achieve the orientation control in this embodiment, each unit pattern is required to have a line symmetry axis that is parallel to the direction Y (axis of easy orientation direction), and is required not to have an axisymmetric axis that is parallel to the direction X or a rotational symmetry axis in the direction normal to the substrate.

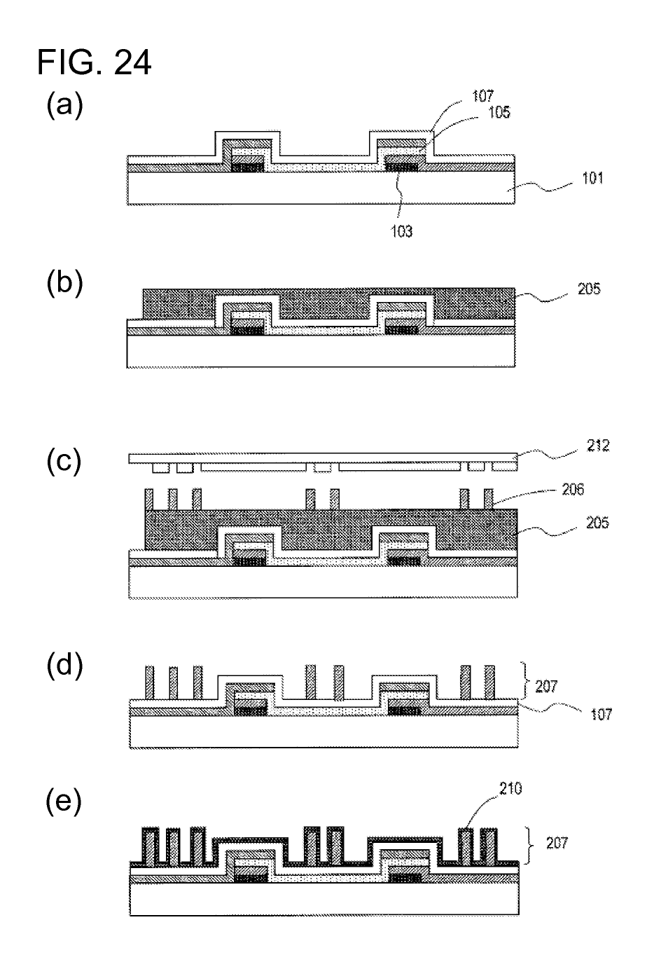

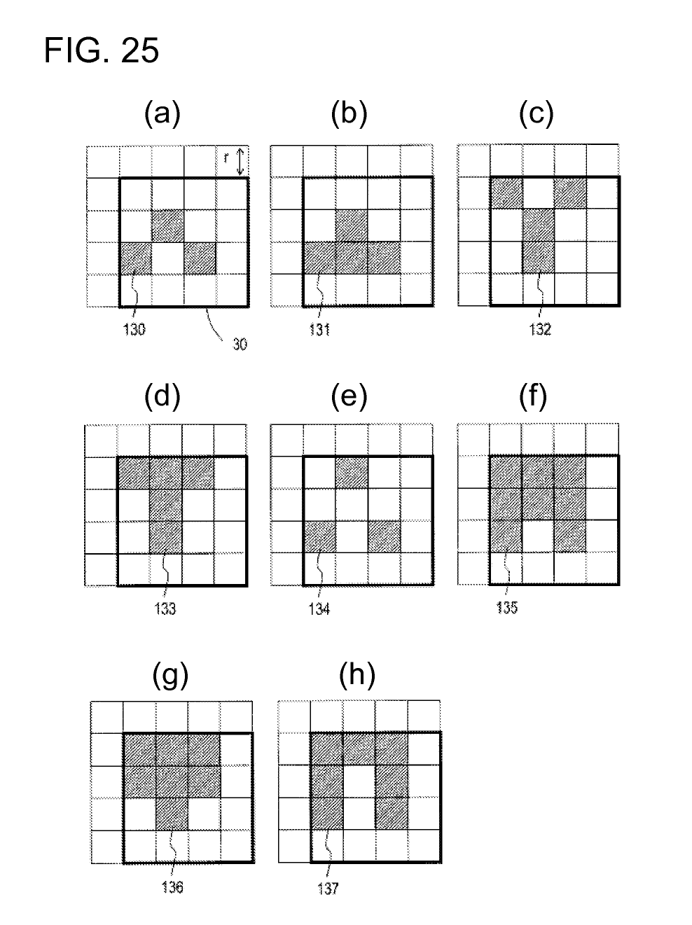

Therefore, regarding sixteen cells (4×4) as one unit, unit patterns that meet all of the aforementioned requirements were studied using nine cells (3×3) in the one unit. The unit was set to be larger than the unit pattern in order to prevent contacts between neighboring unit patterns. As a result, eight types of unit patterns 130 to 137 shown in FIG. 25(a) to FIG. 25(h), respectively, were obtained.

In FIG. 25(a) to FIG. 25(h), the respective unit patterns 130 to 137 are formed in a single unit 30. Each unit 30 is formed of sixteen cells, and each cell has the resolution r of the exposure apparatus as a side. Here, the resolution r is set to 0.8 μm. In the unit 30, the hatched cells are parts of the exposure mask “to be left,” and the cells that are not hatched are parts of the exposure mask “to be removed,” for example. Therefore, the unit patterns 130 to 137 that are formed of cells “to be left” become the shapes of light shielding parts of the respective exposure masks. Furthermore, the length of the respective sides of the unit 30 (0.8 μm×4=3.2 μm) becomes the arrangement pitch P of the unit patterns. When designing the exposure mask to be used for forming the master, parts “to be left” and parts “to be removed” become reversed.

In FIG. 25(a) to FIG. 25(h), only single unit 30 is shown. However, the same unit patterns are designed in the same direction in neighboring units. Therefore, when one unit pattern is translated, it is required that the unit pattern matches the other unit patterns (translation symmetry). If there is no translation symmetry, liquid crystal molecules would be oriented in different directions for each protrusion, and there is a risk of causing disarrayed liquid crystal orientation in a pixel. Translation symmetry is required also because pretilt directions in the respective protrusions are averaged, and a prescribed pretilt may not otherwise be given to liquid crystal molecules located near the middle of the liquid crystal layer in the thickness direction. It is sufficient if a single pixel has a region where a plurality of protrusions are arranged in the same direction, and all of the plurality of protrusions in the single pixel do not have to be arranged in a same direction.

Of unit patterns 130 to 137, the unit patterns 130, 132, 134, 135, and 136 include a small part “to be removed” or a small part “to be left,” formed of a single cell, making exposure difficult. In the unit patterns 130 and 131, because the width along the direction Y is shorter than the length of the linear portion, the desired ratio of W_{Y}/L cannot be obtained. Therefore, it can be said that the unit patterns 133 and 137 shown in FIG. 25(d) and FIG. 25(h) are preferable.

Here, the number of cells forming each unit 30 is set to sixteen. However, the number of cells is not limited to this, and can be selected appropriately. Also, each unit 30 may be a rectangle. In either case, the optimum shape can be selected based on conditions required for the unit pattern.

In the unit patterns 133 and 137 shown in FIG. 25(d) and FIG. 25(h), the ratio W_{Y}/L, which is a ratio of the width W_{Y} along the direction Y to the length L of the linear portion, is 1. Thus, the inventor of the present invention increased the number of cells included in a single unit 30, and examined more preferable unit patterns.

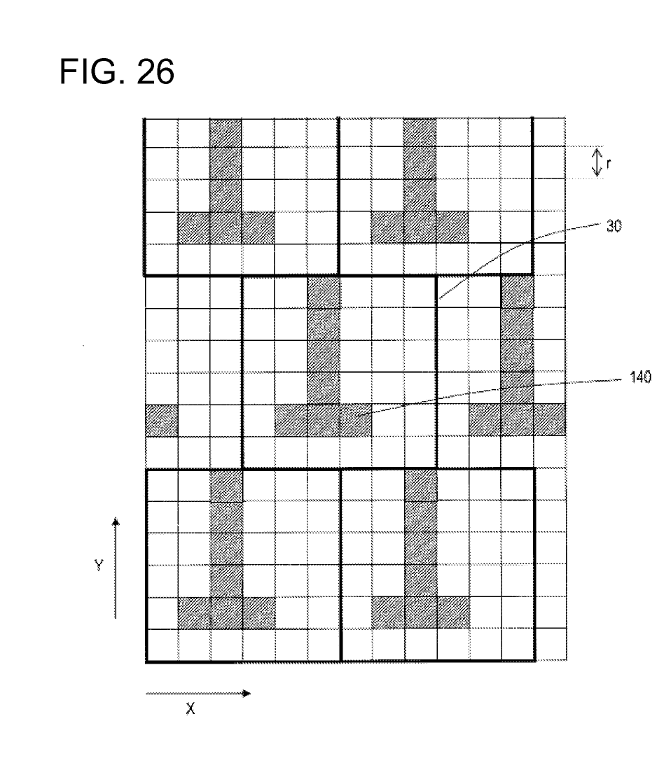

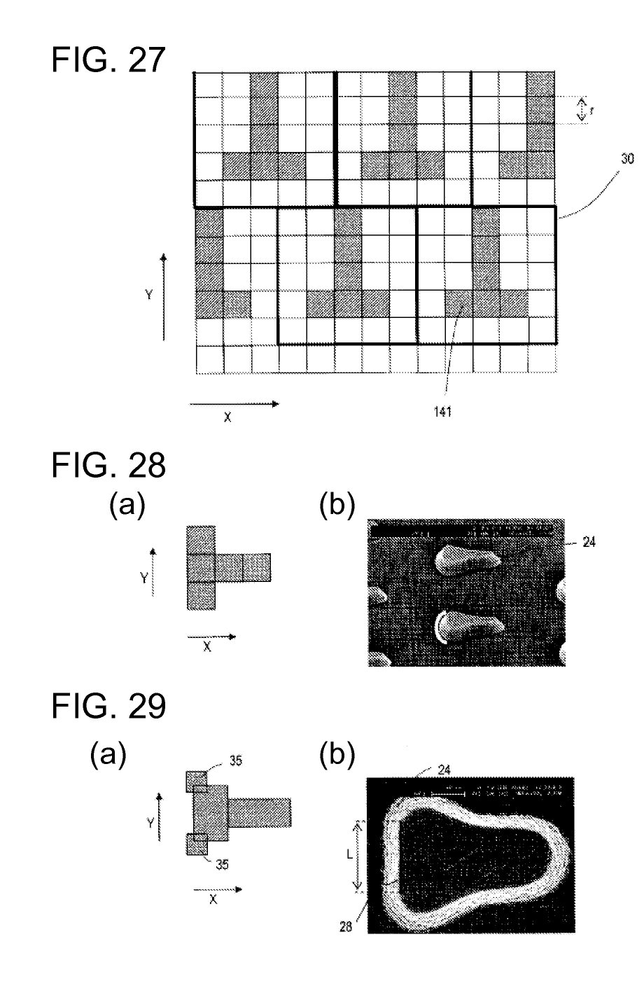

FIG. 26 and FIG. 27 are drawings illustrating more preferable unit patterns, respectively.

In the example shown in FIG. 26, one unit 30 is formed of thirty-six cells (6×6). A unit pattern 140 has a shape in which the length in the direction Y of the T-shape shown in FIG. 25(d) is longer than the length in the direction X by two cells. The ratio W_{Y}/L in the unit pattern is approximately 1.7. Assuming the resolution r is 0.8 μm, the arrangement pitch of the unit patterns 140 is 4.8 μm, the area ratio of the unit patterns (light shielding parts) 140 is approximately 19%.

In the example shown in FIG. 27, one unit 30 is formed of twenty-five cells (5×5). A unit pattern 141 has a shape in which the length in the direction Y of the T-shape shown in FIG. 25(d) is longer than the lengths in the direction X by one cell. The ratio W_{Y}/L in the unit pattern is approximately 1.3. Assuming that the resolution r is 0.8 μm, the arrangement pitch of the unit patterns 141 is 4.0 μm. The area ratio of the unit patterns (light shielding parts) is 24%.

As shown by the examples shown in FIG. 26 and FIG. 27, the ratio W_{Y}/L in the unit pattern can be appropriately adjusted. Also, by altering the size of the unit that includes unit patterns, it is possible to adjust the area ratio. As described above, the ratio W_{Y}/L of the actual protrusions formed becomes larger than the ratio W_{Y}/L of the unit pattern of the mask, and the area ratio of the protrusions becomes smaller than the area ratio of light shielding parts of the mask.

However, even when the mask designed by the aforementioned method is used, there are cases in which the shape that meets the prescribed requirements cannot be obtained due to shape imprecision. For example, even when the mask having the T-shape shown in FIG. 28(a) as the unit pattern is used, shape imprecision may occur depending on performance of the exposure apparatus. As a result, as shown in FIG. 28(b), there may be cases in which the contour shape of the upper surface of the protrusion 24 becomes rounder and the linear portion is not formed. It can be considered that this is because light is diffracted at the periphery of the light shielding parts of the mask.

In such cases, the unit pattern of the mask may be changed so that the protrusion can have a linear portion even when shape imprecision occurs. Specifically, as shown in FIG. 29(a), using a T-shape pattern as the base, an additional pattern 35 is provided to overlap both edges of the part that becomes the linear portion. When a mask having such unit pattern is used, the protrusion 24 having the linear portion 28 can be obtained as shown in FIG. 29(b). The size of the pattern 35 in the mask is appropriately selected so that the length L of the linear portion 28 becomes a desired length. It is preferable that the pattern 35 also has a quadrilateral shape formed only of straight lines extending in the direction X and straight lines extending in the direction Y.

In a conventional method for designing masks, normally, in order to manufacture a structured body having arranged protrusions in a triangular column shape by exposure and development, a mask having a plurality of light shielding parts in a triangular shape is designed. Here, when the arrangement pitch of the protrusions was 3 μm, it was required to perform patterning with the resolution of 0.3 μm. Therefore, it has been difficult to manufacture such a mask using an exposure apparatus that is usually used in a manufacturing process of a display apparatus.

On the other hand, in the method for designing a mask in this embodiment, a mask having unit patterns that are formed of cells is designed. Therefore, each unit pattern is formed only of straight lines extending in the direction X and of straight lines extending in the direction Y, and does not have a line segment that is tilted relative to the directions X and Y. Therefore, even when the resolution is 1 μm, it becomes possible to decrease the arrangement pitch of protrusions to 4 μm. When the resolution is 0.8 μm, it is possible to decrease the arrangement pitch to 3.2 μm. Therefore, a fine pattern that would normally be obtained only by using an EB drawing machine can be formed using a stepper.

In this embodiment, the unit pattern is determined such that the shape of protrusions obtained after exposure and development meets the prescribed conditions by taking into account shape imprecision. Particularly, if the unit pattern is in a T-shape, edges of the T-shape become rounder in the exposure and development process, and a protrusion having the upper surface that is close to a triangular shape can be obtained. If the shape of the upper surface of the protrusion is nearly in a triangular shape—especially in a nearly isosceles triangle having the linear portion as the base, two side walls of the protrusion that face each other (side walls 29p and 29q shown in FIG. 8) become nearly flat, and can effectively orient liquid crystal molecules near the side walls in prescribed directions. Therefore, better orientation control can be achieved.

(3) Simulation Results of Liquid Crystal Orientation

Whether or not the aforementioned orientation control explained with reference to FIG. 8 can be achieved when the shape of protrusions and materials are changed was examined by simulation. The results are explained here.

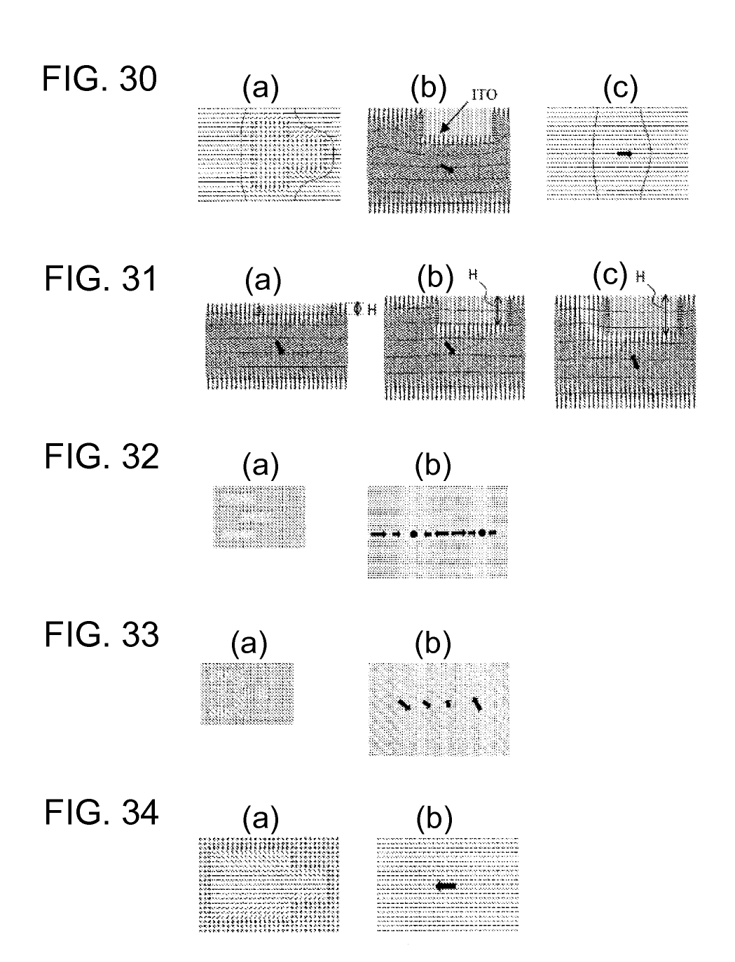

FIG. 30(a) to FIG. 30(c) are simulation results showing liquid crystal orientations formed by protrusions when the conductive film (ITO film) and the vertical alignment film have been formed on the resin layer. FIG. 30(a) shows the orientation of liquid crystal molecules in a cross-section that is parallel to the substrate and that includes the upper surface of the protrusion. FIG. 30(b) shows the orientation of liquid crystal molecules in a cross-section that is parallel to the substrate and that is located in the middle of the liquid crystal layer in the thickness-wise direction. FIG. 30(c) shows the orientation of liquid crystal molecules in a cross-section that is perpendicular to the substrate. From these drawings, it can be confirmed that a prescribed pretilt can be formed even when the ITO film is formed on the resin layer. Also, because potential distribution and pretilt directions formed by the protrusion match, more stable liquid crystal orientation can be obtained.

FIG. 31(a) to FIG. 31(c) are simulation results illustrating a relation between the height H of the protrusion and the liquid crystal orientation examined by changing the height H of the protrusion relative to the thickness of the liquid crystal layer. FIG. 31(a) to FIG. 31(c) show orientations of liquid crystal molecules in a cross-section perpendicular to the substrate, respectively. Based on the results, it can be said that the smaller the height H of the protrusion is, the more stable the liquid crystal orientation can be. When the height H of the protrusion is small, the pretilt becomes small, and as the height H of the protrusion becomes high, the pretilt becomes large. Therefore, the height H is set by considering the size of the pretilt and stability.

FIG. 32 and FIG. 33 are simulation results illustrating liquid crystal orientations when the shape of protrusion is changed. FIG. 32(a) and FIG. 33(a) show orientations of liquid crystal molecules in a cross-section that is parallel to the substrate and that includes the upper surface of the protrusion, respectively. FIG. 32(b) and FIG. 33(b) show orientations of liquid crystal molecules in a cross-section that is parallel to the substrate and that is located in the middle of the liquid crystal layer in the thickness-wise direction, respectively. When the shape of the upper surface of the protrusion is close to a Y-shape as in FIG. 32 and FIG. 33, orientations around the shape are changed in a complex manner. Therefore, it can be said that the distribution of pretilt is not sufficiently averaged, and that it becomes difficult to obtain a uniform orientation of the middle liquid crystal molecules. Thus, it can be said that a better orientation can be achieved if the upper surface of the protrusions is substantially in a triangular shape as in this embodiment.

FIG. 34(a) and FIG. 34(b) are simulation results when orientation control is performed by recesses having a bottom surface in a nearly triangular shape. FIG. 34(a) shows the orientation of liquid crystal molecules in a cross-section that is parallel to the substrate and that includes the upper surface of the protrusion. FIG. 34(b) shows the orientation of liquid crystal molecules in a cross-section that is perpendicular to the substrate. In such a configuration, the respective regions located between adjacent recesses are in a roughly triangular shape as viewed from the direction normal to the substrate, and these regions correspond to the protrusions 24 in this embodiment. Thus, as shown in FIG. 34(a), liquid crystal orientations are confined near the longer side wall (side wall on the left) of the side walls along the direction X of the respective recesses, and the liquid crystal molecules are tilted in the direction of the arrow by the two side walls extending in the direction Y. In order to obtain such orientation, the area ratio of the recesses is required to be 70% or higher. According to this configuration, a pretilt can be formed uniformly in the middle liquid crystal molecules. However, when the ITO film is formed on the resin layer, particularly, the voltage drop increases. Furthermore, direction stability of the liquid crystal orientation can be improved more when orientation control is performed using protrusions.

Because the display apparatus of this embodiment has the aforementioned alignment control body, it can control the orientation of the middle liquid crystal molecules of the liquid crystal layer substantially uniformly, and display having high contrast can be obtained. Also, compared to display apparatuses equipped with conventional orientation control means such as a rib, a slit, or the like, retardation and the aperture ratio can be improved. Furthermore, the liquid crystal orientation (tilt direction and tilt angle of liquid crystal molecules from the line normal to the substrate) can be flexibly set by controlling the shape and arrangements of the unit structures in the alignment control body. Because the alignment control body of this embodiment can be manufactured using an exposure apparatus that is normally used in a display apparatus, the aforementioned display apparatus can be manufactured in a process suitable for mass production.

The display apparatus of this embodiment is preferably an MVA mode liquid crystal display apparatus. When the present invention is applied to an MVA mode liquid crystal display apparatus, orientation division can be achieved flexibly and easily by controlling the direction of the respective protrusions in a pixel to be a preliminarily prescribed direction based on the location. Therefore, unlike conventional methods, complicated orientation control means (a rib, a slit, and the like) are not formed, and the manufacturing process can be simplified. Also, the display apparatus of the present invention has an advantage of achieving excellent response characteristics compared to a display apparatus using the rib or the slit. This advantage is explained below.

The orientation control means, such as the rib, the slit, or the like, used in a conventional MVA-type LCD is disposed locally (one-dimensionally) on a liquid crystal layer in a pixel. Therefore, in a pixel, which expands two-dimensionally, liquid crystal molecules close to the orientation control means respond relatively fast. On the other hand, liquid crystal molecules at locations that are difficult to be affected by the orientation control means respond late. This distribution of response characteristics may degrade the display characteristics.

In the rib method, liquid crystal molecules close to the ribs are affected by the rib pattern, and have a prescribed pretilt (pretilt direction and pretilt angle). On the other hand, liquid crystal molecules located midway between neighboring ribs are less susceptible to the rib pattern, and the pretilt angle here becomes smaller than the pretilt angle of liquid crystal molecules near the ribs. When a voltage is applied to such a liquid crystal layer, response speed of the liquid crystal layer becomes slower because liquid crystal molecules fall over in the pretilt direction in the order starting with the liquid crystal molecules with a larger pretilt.

Similarly, in the oblique electric field method, between liquid crystal molecules near slits and liquid crystal molecules located midway between neighboring slits, the liquid crystal molecules close to slits are more susceptible to the oblique electric field. Therefore, when a voltage is applied, liquid crystal molecules respond in the order starting with the liquid crystal molecules closer to the slits. Therefore, the response time of the liquid crystal layer becomes long.

On the other hand, in the display apparatus of this embodiment, liquid crystal molecules can respond fast no matter where they are located in the liquid crystal layer because orientation control means of the liquid crystal layer can be formed uniformly in nearly all the regions (two-dimensionally) in the pixel region. Therefore, the response speed of the liquid crystal layer can be significantly improved compared to the conventional display apparatuses.

In a ZBD (Zenithal Bistable Device) that functions in a bistable liquid crystal mode, the liquid crystal orientation is also controlled by using a recessed and projected pattern. Orientation control in a ZBD is disclosed in Japanese translation of PCT international application No. 2002-500383, Japanese translation of PCT international application No. 2003-515788, and the like. In the ZBD, there are two or more liquid crystal orientation states (pretilts) determined by an alignment film having a recessed and protrusion pattern, and these orientation states can be switched by applying different polarity voltages. The respective orientation states are retained, as is, when no voltage is applied. On the other hand, in the present invention, the orientation state (pretilt angle, pretilt direction) determined by the recessed and projected pattern of the alignment control body does not change when different polarity voltages (−5V to +5V, for example) are applied. Therefore, it does not show bistability. In a bistable liquid crystal mode liquid crystal display apparatus, there is generally a problem of the hysteresis in transmittance with respect to the applied voltage. However, in the liquid crystal display apparatus of the present invention, such hysteresis in transmittance does not occur, and excellent halftone display can be obtained.

### Embodiment 2

With reference to figures, Embodiment 2 of a display apparatus according to the present invention is explained below. The liquid crystal display apparatus of this embodiment is an MVA mode display apparatus having an alignment control body that is divided into a plurality of sub-regions.

In a manner similar to the configuration explained with reference to FIG. 4, a display apparatus of this embodiment has a front substrate that is a CF substrate having a plurality of protrusions thereon, a back substrate, and a liquid crystal layer disposed between these substrates. The front substrate functions as the alignment control body.

The display apparatus of this embodiment also has a plurality of pixels. Each pixel has four subpixels having different pretilt directions. The alignment control body (front substrate) has a plurality of unit regions corresponding to pixels in the display apparatus. Each unit region is divided into a plurality of subregions. These subregions form pretilts in different directions in the respective subpixels.

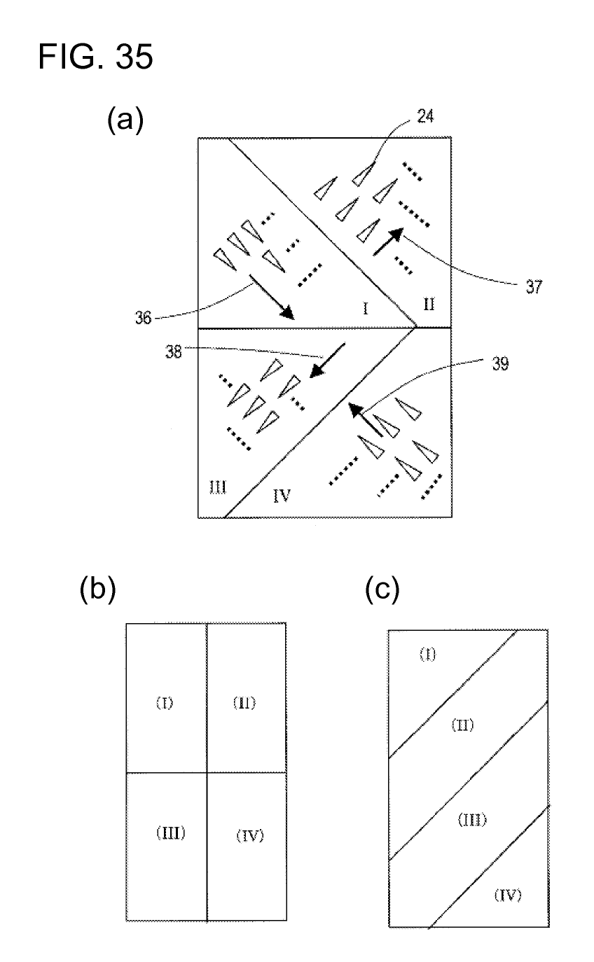

FIG. 35(a) is a schematic top view showing the single unit region of the alignment control body of this embodiment. Each unit region is divided into four subregions Ito IV. In the subregion I, the respective protrusions 24 are arranged such that the direction shown by the arrow 36 becomes the pretilt direction. Similarly, in subregions II to IV, the respective protrusions 24 are arranged such that the directions shown by the arrows 37 to 39 become the pretilt directions, respectively. In this embodiment, the pretilt direction 36 in the subregion I and the pretilt direction 39 in the subregion IV are opposite to each other, and the pretilt direction 37 in the subregion II and the pretilt direction 38 in the subregion III are opposite to each other. The pretilt directions 36 and 39 are orthogonal to the pretilt directions 37 and 38. In other words, the direction (direction X) along the linear portions of the protrusions 24 in the subregions I and IV and the direction (direction X) along the linear portions of the protrusions 24 in the subregions II and III are orthogonal to each other. Although not shown in the figure, all of the pretilt directions 36 to 39 are set to form a 45° angle from the absorption axes of the polarizing plates of the liquid crystal display apparatus of this embodiment.

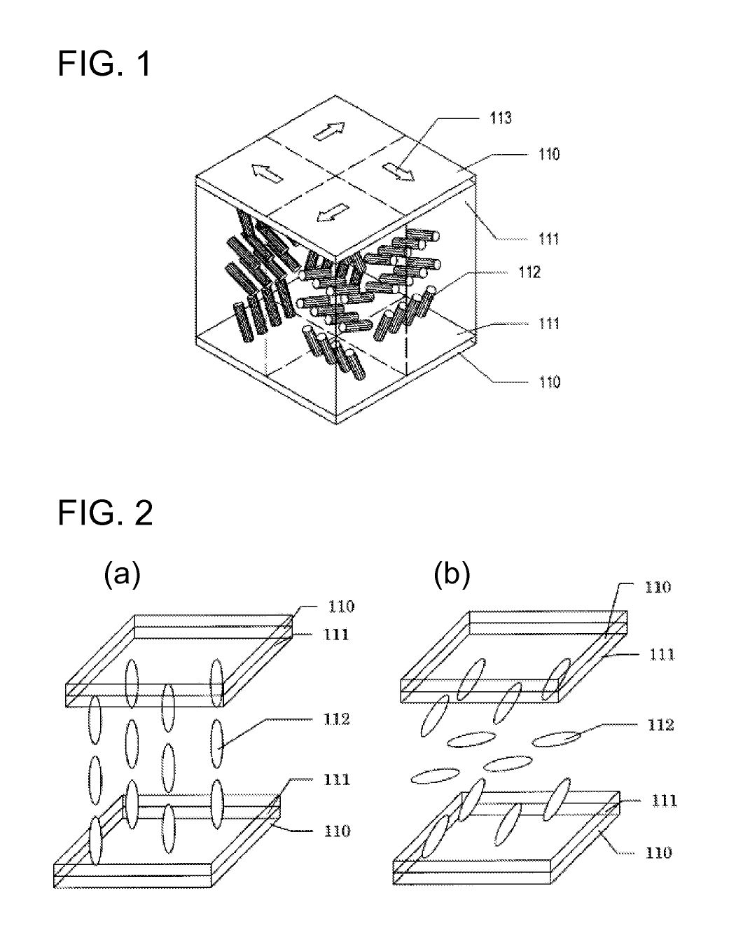

According to this embodiment, one pixel can be divided into a plurality of subregions having different pretilt directions by changing the direction of protrusions 24 in each subregion. Therefore, the aforementioned MVA orientation described with reference to FIG. 1 and FIG. 2 can be achieved.

The division pattern of the alignment control body in this embodiment is not limited to the division pattern shown in FIG. 35(a). Each pixel (thus, each unit region) needs to be divided such that each pixel has at least two regions having mutually different directions X of the protrusions 24. It is preferably divided to meet the following two conditions.

First, in the VAN mode, liquid crystal molecules fall over when a voltage is applied, and the bright state is achieved by the birefringence. A pair of polarizing plates having a liquid crystal cell disposed between them are disposed such that their absorption axes form 90°. Therefore, in order to efficiently use birefringence, it is preferable that the direction in which liquid crystal molecules fall over (pretilt direction) and the absorption axes of the respective polarizing plates form an angle of 45° as viewed from the direction normal to the substrate. Therefore, when the pixel is divided into four, it is preferable that the protrusions 24 be arranged such that the direction (pretilt direction) perpendicular to the linear portions of the protrusions 24 in each of the four subregions forms a 45° angle to the absorption axes of polarizing plates.

Second, the number of subregions in a single unit region (the number of division) is either two or four, and the areas of these subregions preferably are the same. The areas of the subregions within the pixel unit are required to be the same, but the areas of subregions may be different in different pixels.

Other examples of division patterns of the unit region that meet the aforementioned first and second conditions are shown in FIG. 35(b) and FIG. 35(c). The aforementioned division patterns are applied to one or both of the pair of substrates disposed to face each other having the liquid crystal layer between them in a display apparatus.

The alignment control body in this embodiment may be manufactured by photolithography (exposure) or by transfer using a master. When the master is used, a master having a pattern corresponding to the aforementioned division pattern may be formed. Alternatively, a master corresponding to one subregion may be formed, and an alignment control body having protrusions in different directions in the respective subregions may be formed by transferring the surface pattern of the master four times in different directions in different regions.

Particularly, when a liquid crystal panel is manufactured using a large substrate having a side of 1 m or longer, a replica method in which the master is manufactured and is transferred onto a surface of the substrate is suitably used in order to form recesses and protrusions that control the liquid crystal orientation. However, because aligning the master and the substrate is very difficult, a division pattern that does not require an alignment is desired.

A division pattern that does not require an alignment of the master and the substrate with a high degree of accuracy when the surface pattern of the master is transferred onto the surface of the substrate is explained below.

A division pattern of the unit region in the MVA mode requires a single pixel to be precisely divided into subregions of the same size so that luminance changes are the same when the viewing angle is tilted upward, downward, to the left, or to the right. However, as long as the subregions are equal in size, the location of the respective subregions and the order in which they are arranged do not affect display. Therefore, the sizes of subregions and unit regions are set such that a plurality of subregions are included in a single unit region, and a set (subregion group) of subregions that are arranged consecutively is formed on a master. Here, the total areas of the respective subregions are preferably roughly equal. In this way, the total areas of the respective subregions included in the respective unit regions (pixels) in the substrate can be substantially equal even when the pattern of the master is transferred onto the substrate without performing an alignment with a high degree of accuracy.

When the liquid crystal orientation of the display apparatus of this embodiment is examined, it can be confirmed that the middle liquid crystal molecules are tilted (pretilted) and are vertically oriented from the normal line direction relative to the substrate when a voltage is not applied to the liquid crystal layer. When a voltage is applied to the liquid crystal layer, it can be confirmed that the liquid crystal orientation is divided into four regions with each region having a different direction in which liquid crystal molecules fall over.

As described above, according to the present invention, the liquid crystal orientation can be controlled with a high degree of accuracy because a roughly uniform pretilt can be formed in liquid crystal molecules located in the middle of the vertical alignment liquid crystal layer in the thickness-wise direction by the recesses and protrusions formed on the surface in contact with the liquid crystal layer. Therefore, a bright liquid crystal display apparatus having high contrast can be obtained. Furthermore, the pretilt angle and the pretilt direction can be set flexibly by optimizing the shape, size, and arrangement of the unit structures that are two-dimensionally arranged on the surface adjacent to the liquid crystal layer.

In addition, because the orientation of the liquid crystal layer can be controlled by a plane, a higher response characteristic than a conventional display apparatus using the rib method or the oblique electric field method can be achieved.

By altering the directions of the protrusions depending on the location on the substrate surface, a single pixel can be divided into a plurality of regions having different pretilt directions, effectuating orientation division. Thus, a liquid crystal display apparatus having excellent viewing angle characteristics can be provided.

The alignment control structure (recesses and protrusions) of the present invention is favorable because it can be formed in a simpler process than conventional means of alignment control. Specifically, mass productivity can be improved because an alignment control structure that can form a prescribed pretilt can be formed with exposure apparatus typically used to manufacture a display apparatus.

### INDUSTRIAL APPLICABILITY

The present invention can be applied to various types of vertical alignment liquid crystal display apparatuses. Especially, it can be suitably applied to the MVA mode liquid crystal display apparatus.

### DESCRIPTION OF REFERENCE CHARACTERS

1 front substrate (alignment control body)
2 back substrate
10 TFT substrate
12 CF substrate
14 liquid crystal layer
16 liquid crystal molecule
18 electrode layer
20 resin layer
22 vertical alignment film
24 protrusion
100 liquid crystal display apparatus

1. A liquid crystal display apparatus, comprising:
a pair of substrates;
a vertical alignment liquid crystal layer disposed between said pair of substrates; and
an electrode that applies a voltage to said vertical alignment liquid crystal layer,
wherein at least one of said pair of substrates has a plurality of protrusions on a surface in contact with said vertical alignment liquid crystal layer,
wherein each protrusion is substantially in a shape of a column,
wherein a contour of an upper surface of each said protrusion includes a linear portion extending in a substantially straight line along a direction X, where the direction X is a direction in a plane paralleled to said one of the substrates, a direction perpendicular to direction X in the place being a direction Y.
wherein a shape of the contour of the upper surface of each said protrusion has line symmetry with respect to an axis along said direction Y, does not have linear symmetry with respect to an axis along said direction X, and does not have a rotational symmetry axis in a direction normal to said one of the substrates,
wherein W_{Y}/L where Y is a length of the upper surface of each said protrusion in said direction Y and L is a length of said linear portion is at least 1.6 but no more than 2.5,
wherein, viewed from a direction normal to said one of the substrates, an area ratio of a region where said plurality of protrusions have been formed to an overall surface in contact with said vertical alignment liquid crystal layer is no more than 30%, and
wherein liquid crystal molecules located in a middle of said vertical alignment liquid crystal layer in a thickness-wise direction are pretilted towards said direction Y from a direction normal to said pair of substrates when no voltage is applied.

2. The liquid crystal display apparatus according to claim 1, wherein the upper surface of protrusions has a substantially triangular shape having said linear portion as a base.

3. The liquid crystal display apparatus according to claim 1, wherein said area ratio is 15% or higher.

4. The liquid crystal display apparatus according to claim 1, wherein said area ratio is no more than 20%.

5. The liquid crystal display apparatus according to claim 1, wherein an angle formed by a side surface of each said protrusion and a surface of said one of the substrates is at least 70° but no more than 95°.

6. The liquid crystal display apparatus according to claim 1, wherein at least one arrangement pitch P of arrangement pitches of said plurality of protrusions in the direction X and in the direction Y and a height H of each said protrusion satisfy 0.15≦H/P≦0.2.

7. The liquid crystal display apparatus according to claim 1, further comprising an electrode layer between said one of the substrates and said plurality of protrusions,
wherein said plurality of protrusions comprise a resin layer having columnar structures corresponding to said plurality of protrusions and a vertical alignment film formed on a surface of said resin layer, and
wherein said vertical alignment film is in contact with said vertical alignment liquid crystal layer.

8. The liquid crystal display apparatus according to claim 1, further comprising an electrode layer between said one of the substrates and said plurality of protrusions,
wherein said plurality of protrusions comprise a resin layer having columnar structures corresponding to said plurality of protrusions, an electrode layer formed on a surface of said resin layer, and a vertical alignment film formed on a surface of said electrode layer, and
wherein said vertical alignment film is in contact with said vertical alignment liquid crystal layer.

9. The liquid crystal display apparatus according to claim 1,
wherein said pair of substrates comprises a front substrate disposed on a viewer side of said vertical alignment liquid crystal layer and a back substrate that is disposed on a back side of said vertical alignment liquid crystal layer and that has a plurality of switching elements, and
wherein said plurality of protrusions are formed only on said front substrate.

10. The liquid crystal display apparatus according to claim 1,
wherein said pair of substrates comprises a front substrate disposed on a viewer side of said vertical alignment liquid crystal layer and a back substrate that is disposed on the back side of said vertical alignment liquid crystal layer and that has a plurality of switching elements, and
wherein said plurality of protrusions are formed only on said back substrate.

11. The liquid crystal display apparatus according to claim 1, including a plurality of pixels arranged in a matrix, wherein each pixel comprises a first region where said direction X is a first direction and a second region where said direction X is a second direction that is different from said first direction.

12. A method for manufacturing the liquid crystal display apparatus as set forth in claim 1, the method comprising:
a step (A) of preparing a substrate having a plurality of protrusions formed thereon; and
a step (B) of disposing said substrate and another substrate to face each other and providing a vertical alignment liquid crystal layer between said substrate and said another substrate.

13. The method for manufacturing the liquid crystal display apparatus according to claim 12,
wherein the upper surface of each said protrusion has a substantially triangular shape,
wherein said step (A) comprises a step (a1) of forming a photoresist layer on said substrate, and a step (a2) of performing exposure of said photoresist layer using a mask having a pattern corresponding to the upper surface of said plurality of protrusions, and
wherein said pattern of said mask comprises a unit pattern formed only of straight lines extending along one direction and of straight lines extending along another direction that is perpendicular to said one direction.

14. The method for manufacturing the liquid crystal display apparatus according to claim 12, wherein said step (A) comprises a step (A1) of preparing a master having a plurality of recesses thereon corresponding to said plurality of protrusions and a step (A2) of transferring a surface pattern of said master onto a surface of said substrate.

15. The method for manufacturing the liquid crystal display apparatus according to claim 14,
wherein the upper surface of each said protrusion has a substantially triangular shape,
wherein said step (A1) comprises a step (a1) of forming a photoresist layer on a support substrate and a step (a2) of performing exposure of said photoresist layer using a mask having a pattern corresponding to the upper surface of said plurality of recesses, and
wherein said pattern of said mask comprises a unit pattern formed only of straight lines extending along one direction and of straight lines extending along another direction that is perpendicular to said one direction.

16. The method for manufacturing the liquid crystal display apparatus according to claim 13,
wherein said step (a2) is performed using an exposure apparatus having a resolution of at least 0.5 μm but no more than 1.0 μm, and
wherein said unit pattern is formed of a combination of a plurality of squares having a side the length of which is equal to the resolution of said exposure apparatus or formed of a combination of a plurality of larger squares or larger rectangles.
